(19) United States
(12) Patent Application Publication
(10) Pub. No.: US 2007/0134821 A1
(43) Pub. Date: Jun. 14, 2007

(54) CLUSTER TOOL FOR ADVANCED FRONT-END PROCESSING

(76) Inventors: Randhir Thakur, San Jose, CA (US); Arkadii Samoilov, Sunnyvale, CA (US); Per-Ove Hansson, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/460,864

(22) Filed: Jul. 28, 2006

Related U.S. Application Data
(63) Continuation-in-part of application No. 11/286,063, filed on Nov. 22, 2005.
(60) Provisional application No. 60/630,501, filed on Nov. 22, 2004.
(60) Provisional application No. 60/642,877, filed on Jan. 10, 2005.

(51) Int. Cl. B08B 6/00; H01L 21/00; C23C 16/00

(52) U.S. Cl. 438/5; 118/719; 134/1.3

(57) ABSTRACT

Aspects of the invention generally provide an apparatus and method for processing substrates using a multi-chamber processing system that is adapted to process substrates and analyze the results of the processes performed on the substrate. In one aspect of the invention, one or more analysis steps and/or precleaning steps are utilized to reduce the effect of queue time on device yield. In one aspect of the invention, a system controller and the one or more analysis chambers are utilized to monitor and control a process chamber recipe and/or a process sequence to reduce substrate scrap due to defects in the formed device and device performance variability issues. Embodiments of the present invention also generally provide methods and a system for repeatably and reliably forming semiconductor devices used in a variety of applications.

### CROSS-REFERENCE TO RELATED APPLICATIONS

This application is a continuation-in-part of the U.S. patent application Ser. No. 11/286,063, filed Nov. 22, 2005, which claims benefit of U.S. Provisional Patent Application Ser. No. 60/630,501, filed Nov. 22, 2004, and U.S. Provisional Patent Application Ser. No. 60/642,877, filed Jan. 10, 2005, which are all herein incorporated by reference.

### BACKGROUND OF THE INVENTION

1. Field of the Invention

Embodiments of the invention generally relates to an integrated processing system configured to perform processing sequences which include both substrate processing modules, substrate preparation chambers and/or process verification and analysis chambers.

2. Description of the Related Art

The process of forming semiconductor device is commonly done in a multi-chamber processing system (e.g., a cluster tool) which has the capability to process substrates, (e.g., semiconductor wafers) in a controlled processing environment. A typical controlled processing environment will include a system that has a mainframe which houses a substrate transfer robot which transports substrates between a load lock and multiple vacuum processing chambers which are connected to the mainframe. The controlled processing environment has many benefits which include minimizing contamination of the substrate surfaces during transfer and during completion of the various substrate processing steps. Processing in a controlled environment thus reduces the number of generated defects and improves device yield.

The effectiveness of a substrate fabrication process is often measured by two related and important factors, which are device yield and the cost of ownership (CoO). These factors are important since they directly affect the cost to produce an electronic device and thus a device manufacturer's competitiveness in the market place. The CoO, while affected by a number of factors, is greatly affected by the yield of devices formed during a device processing sequence and the substrate throughput, or simply the number of substrates per hour. A process sequence is generally defined as the sequence of device fabrication steps, or process recipe steps, completed in one or more processing chambers in the cluster tool. A process sequence may generally contain various substrate (or wafer) fabrication processing steps.

The push in the industry to shrink the size of semiconductor devices to improve device processing speed and reduce the generation of heat by the device, has caused the industry's tolerance to process variability to shrink. Due to the shrinking size of semiconductor devices and the ever increasing device performance requirements, the amount of allowable variability of the device fabrication process uniformity and repeatability has greatly decreased. One factor that can affect device performance variability and repeatability is known as the “queue time.” Queue time is generally defined as the time a substrate can be exposed to the atmospheric or other contaminants after a first process has been completed on the substrate before a second process must be completed on the substrate to prevent some adverse affect on the fabricated device's performance. If the substrate is exposed to atmospheric or other sources of contaminants for a time approaching or longer than the allowable queue time, the device performance may be affected by the contamination of the interface between the first and second layers. Therefore, for a process sequence that includes exposing a substrate to atmospheric or other sources of contamination, the time the substrate is exposed to these sources must be controlled or minimized to prevent device performance variability. Therefore, a useful electronic device fabrication process must deliver uniform and repeatable process results, minimize the affect of contamination, and also meet a desired throughput to be considered for use in a substrate processing sequence.

Semiconductor device manufacturers spend a significant amount of time trying to reduce CoO issues created by substrate scrap due to misprocessed substrates, device defects or varying performance of the formed devices. Typically, misprocessed substrates, device defects and/or varying device performance are caused by process drift in one or more of the processing chambers in a processing sequence, contamination found in the system or process chambers, or varying starting condition(s) of the substrate or layers of substrates of the substrate. Conventional methods used to assure that the process results are within a desired process window often utilize one or more off-line analysis techniques. Off-line testing and analysis techniques require the periodic or often constant removal of one or more substrates from the processing sequence and processing environment, which are then delivered into a testing environment. Thus, production flow is effectively disrupted during transfer and inspection of the substrates. Consequently, conventional metrology inspection methods can drastically increase overhead time associated with chip manufacturing. Further, because such an inspection method is conducive only to periodic sampling due to the negative impact on throughput, many contaminated substrates can be processed without inspection resulting in fabrication of defective devices. Problems are compounded in cases where the substrates are redistributed from a given batch making it difficult to trace back to the contaminating source. Thus, what is needed is an integrated metrology and process inspection system, that is capable of examining a substrate for selected important device characteristics, which may include film stress, film composition, particles, processing flaws, etc. and then on-the-fly adjustment of the processing conditions to correct problems from occurring on subsequently processed substrates. Preferably, such an inspection can be performed prior to, during, and after substrate processing, thereby determining real time pre-processing and post-processing conditions of the substrate.

Therefore, there is a need for a system, a method and an apparatus that can process a substrate so that it can meet the required device performance goals and increase the system throughput and thus reduce the process sequence CoO.

### SUMMARY OF THE INVENTION

The present invention generally provides a substrate processing apparatus comprising one or more walls that form a transfer region which has a robot disposed therein a first support chamber disposed within the transfer region and is adapted to measure a property of a surface of the substrate, and a substrate processing chamber in communication with the transfer region.

Embodiments of the invention further provide a substrate processing apparatus comprising one or more walls that form a transfer region which has a robot disposed therein, one or more substrate processing chambers that are in communication with the transfer region, a support chamber that is in communication with the robot, wherein the support chamber is adapted to measure a property of a region of the substrate, a substrate processing chamber that is in communication with the transfer region, and a preclean chamber that is adapted to prepare a surface of a substrate before performing a processing step in the substrate processing chamber.

Embodiments of the invention further provide a method of forming a semiconductor device in a cluster tool, comprising forming a device feature on a surface of a substrate in a substrate processing chamber using a device forming process, positioning a substrate in a support chamber and measuring a property of a region on the surface of the substrate, comparing the measured property with values stored in a system controller, and modifying a process parameter during the device forming process based on the comparison of the measured property and the values stored in the system controller.

Embodiments of the invention further provide a method of forming a semiconductor device in a cluster tool, comprising forming a device feature on a surface of a substrate in a substrate processing chamber using a device forming process, positioning a substrate in a transferring region of the cluster tool using a robot that is disposed within the transferring region, measuring a property of the surface of the substrate that is positioned in the transferring region, comparing the measured property with values stored in a system controller, and modifying a process parameter during a device forming process based on the comparison of the measured property and the values stored in the system controller.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a typical prior art processing system for semiconductor processing wherein the present invention may be used to advantage;

FIG. 2 is a plan view of a processing system containing processing chambers and metrology chambers adapted for semiconductor processing wherein the present invention may be used to advantage;

FIG. 3 is a plan view of a processing system containing processing chambers and metrology chambers adapted for semiconductor processing wherein the present invention may be used to advantage;

FIG. 4 is a plan view of a processing system containing processing chambers and metrology chambers adapted for semiconductor processing wherein the present invention may be used to advantage;

FIG. 5 illustrates a processing sequence that contains a series of process recipe steps and substrate transfer steps wherein the present invention may be used to advantage;

FIG. 6 is side cross-sectional view of a support chamber adapted for semiconductor processing wherein the present invention may be used to advantage;

FIG. 7 is side cross-sectional view of a support chamber adapted for semiconductor processing wherein the present invention may be used to advantage;

FIG. 8 is a cross-sectional view of a transfer chamber and support chamber adapted for semiconductor processing wherein the present invention may be used to advantage;

FIG. 9 is a cross-sectional view of a transfer chamber and support chamber adapted for semiconductor processing wherein the present invention may be used to advantage;

FIG. 10 is a cross-sectional view of a transfer chamber and support chamber adapted for semiconductor processing wherein the present invention may be used to advantage;

FIG. 11 is a cross-sectional view of a transfer chamber and support chamber adapted for semiconductor processing wherein the present invention may be used to advantage;

FIG. 12 is side cross-sectional view of a preclean chamber adapted for semiconductor processing wherein the present invention may be used to advantage;

FIG. 13 illustrates a processing sequence that contains a series of process recipe steps and substrate transfer steps wherein the present invention may be used to advantage;

FIG. 14 illustrates a processing sequence that contains a series of process recipe steps and substrate transfer steps wherein the present invention may be used to advantage;

FIG. 15 is a plan view of a processing system containing processing chambers, preprocessing chambers and metrology chamber adapted for semiconductor processing wherein the present invention may be used to advantage;

FIG. 16 illustrates a processing sequence that contains a series of process recipe steps and substrate transfer steps wherein the present invention may be used to advantage;

FIG. 17 is side cross-sectional view of a substrate processing chamber adapted for semiconductor processing wherein the present invention may be used to advantage.

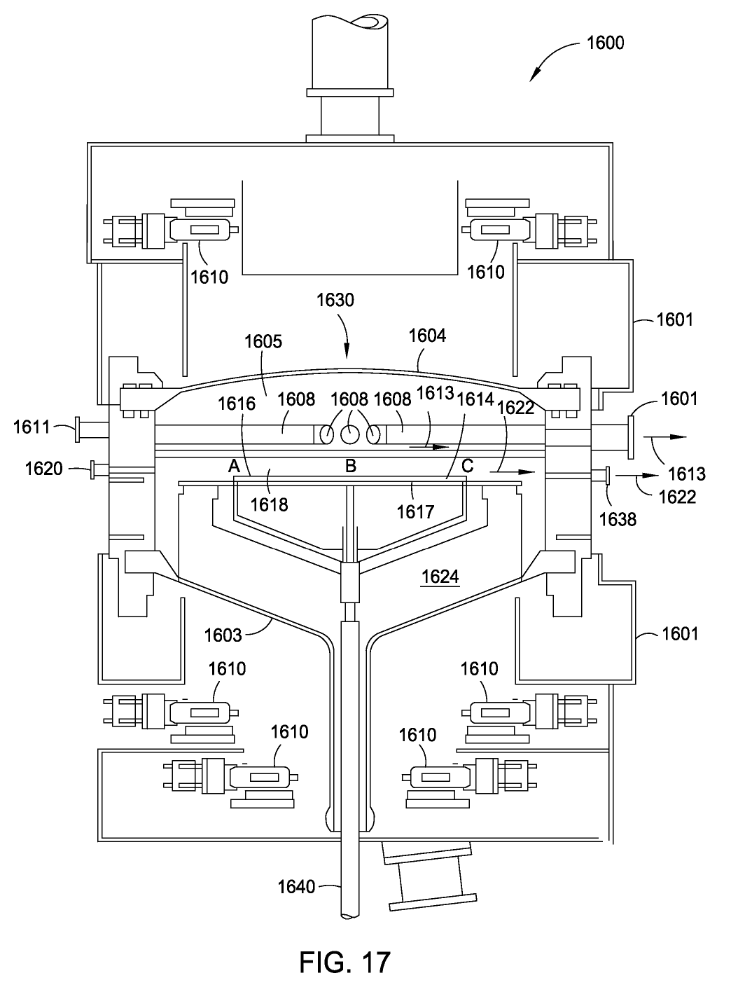

### DETAILED DESCRIPTION

The present invention generally provides an apparatus and method for processing substrates using a multi-chamber processing system (e.g., a cluster tool) that is adapted to process substrates and analyze the results of the processes performed on the substrate. In one aspect of the invention, one or more analysis steps and/or precleaning steps are utilized to reduce the effect of queue time on device yield. In one aspect of the invention, a system controller and the one or more analysis chambers are utilized to monitor and control a process chamber recipe and/or a process sequence to reduce substrate scrap due to defects in the formed device and device performance variability issues. Embodiments of the present invention also generally provide methods and a system for repeatably and reliably forming semiconductor devices used in a variety of applications. The invention is illustratively described below in reference to a Centura, available from the FEP division of Applied Materials, Inc., Santa Clara, Calif.

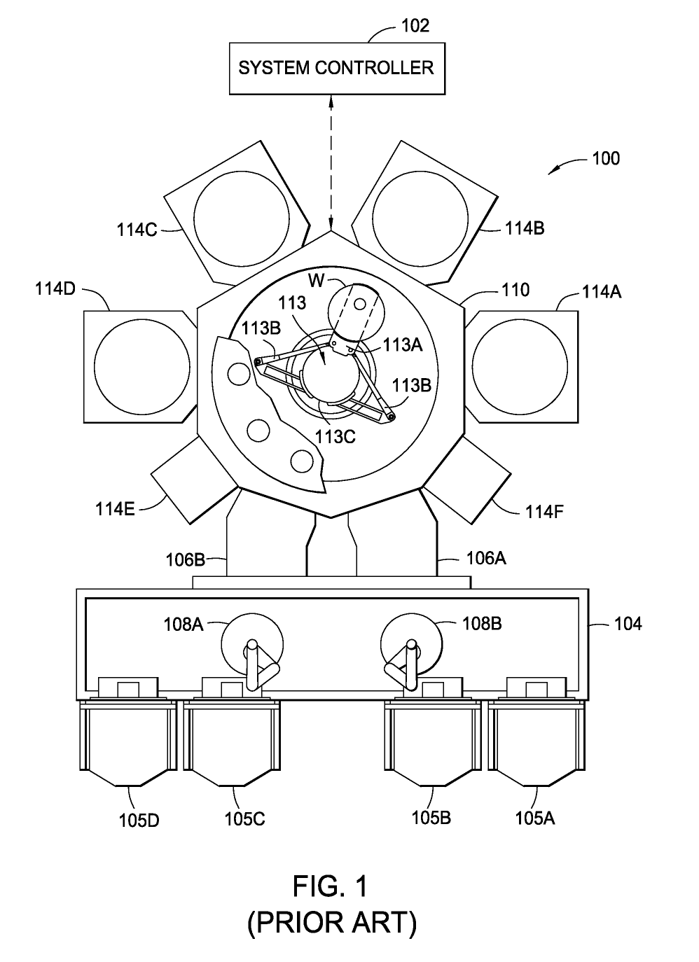

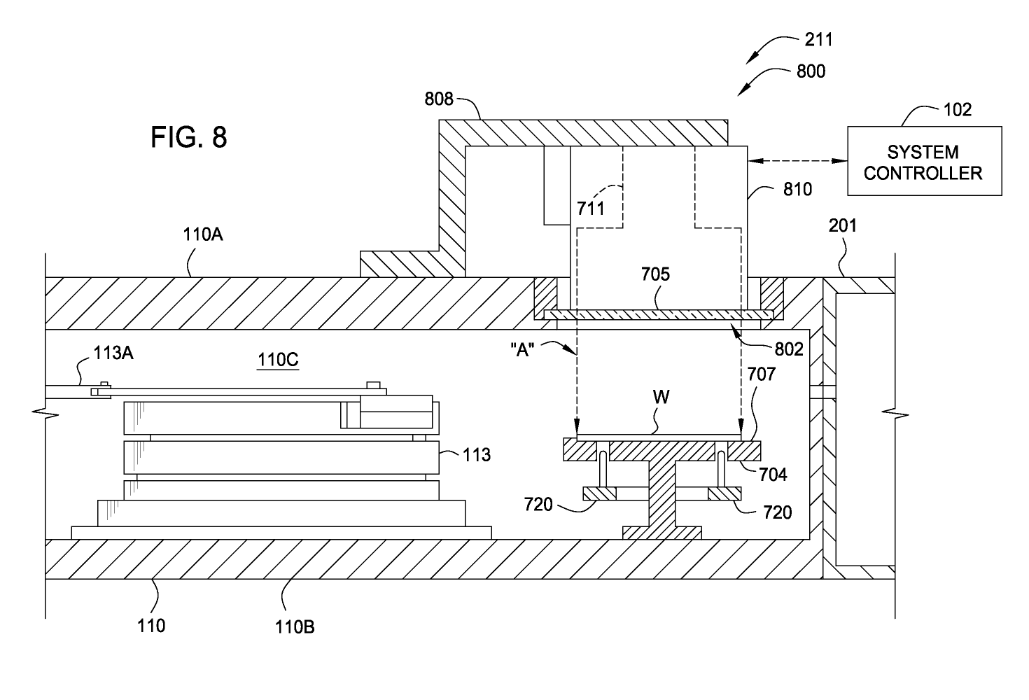

Embodiments of the invention may be advantageously used in a cluster tool configuration that has the capability to process substrates in multiple single substrate processing chambers and/or multiple batch type processing chambers. A cluster tool is a modular system comprising multiple chambers that perform various processing steps that are used to form an electronic device. As shown in FIG. 1, the cluster tool 100 contains multiple processing positions 114A-114F in which processing chambers (not shown) can be mounted to a central transfer chamber 110 which houses a robot 113 that is adapted to shuttle substrates between the processing chambers. The internal region (e.g., transfer region 110C in FIG. 8) of the transfer chamber 110 is typically maintained at a vacuum condition and provides an intermediate region in which to shuttle substrates from one chamber to another and/or to a load lock chamber positioned at a front end of the cluster tool. The vacuum condition is typically achieved by use of one or more vacuum pumps (not shown), such as a conventional rough pump, Roots Blower, conventional turbo-pump, conventional cryo-pump, or combination thereof. Alternately, the internal region of the transfer chamber 110 may be an inert environment that is maintained at or near atmospheric pressure by continually delivering an inert gas to the internal region. FIG. 1 is a plan view of a typical cluster tool 100 for electronic device processing wherein the present invention may be used to advantage. Three such platforms are the Centura, the Endura and the Producer system all available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

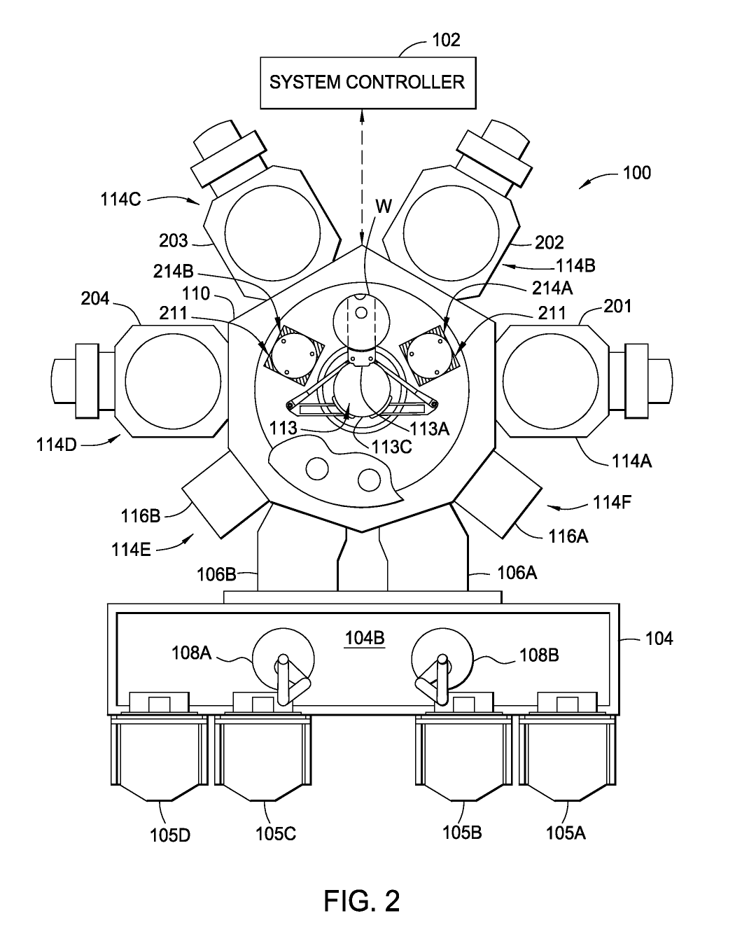

FIG. 2 illustrates one embodiment of a cluster tool, in which substrate processing chambers 201, 202, 203 and 204 are mounted in position 114A, 114B, 144C, and 114D on the transfer chamber 110, respectively. In accordance with aspects of the present invention, the cluster tool 100 generally comprises a plurality of chambers and robots, and is preferably equipped with a system controller 102 programmed to control and carry out the various processing methods and sequences performed in the cluster tool 100. A plurality of slit valves (not shown) can be added to the transfer chamber 110 to selectively isolate each of the process chambers mounted in positions 114A-F so that each chamber may be separately evacuated to perform a vacuum process during the processing sequence. In some embodiments of the invention, not all of the positions 114A-F are occupied with processing chambers to reduce cost or complexity of the system.

In one aspect of the invention, one or more of the substrate processing chambers 201-204 may be a conventional epitaxial (EPI) deposition chamber which can be used to form an epitaxial layer containing one or more materials, such as silicon (Si), silicon germanium (SiGe), silicon carbon (SiC), on a substrate during one or more steps in the substrate processing sequence. An EPI process may be conducted using an Applied Centura EPI chamber, which is available from Applied Materials Inc. located in Santa Clara, Calif. In one aspect of the invention, one or more of the substrate processing chambers 201-204 may be an RTP chamber which can be used to anneal the substrate during one or more steps in the substrate processing sequence. An RTP process may be conducted using an RTP chamber (e.g., Vantage RadOx RTP, Vantage RadiancePlus RTP) and related processing hardware commercially available from Applied Materials Inc. located in Santa Clara, Calif.

In another aspect of the invention, one or more of the substrate processing chambers 201-204 may be a conventional CVD chamber that is adapted to deposit a metal (e.g., titanium, copper, tantalum), semiconductor (e.g., silicon, silcon germanium, silicon carbon, germanium), or dielectric layer (e.g., Blok™, silicon dioxide, SiN, HfOₓ, SiCN). Examples of such CVD process chambers include DXZ™ chambers, Ultima HDP-CVD™ chamber and PRECISION 5000® chamber, commercially available from Applied Materials, Inc., Santa Clara, Calif. In another aspect of the invention, one or more of the substrate processing chambers 201-204 may be a conventional PVD chamber. Examples of such PVD process chambers include Endura^{TM} PVD processing chambers, commercially available from Applied Materials, Inc., Santa Clara, Calif. In another aspect of the invention, one or more of the substrate processing chambers 201-204 may be a decoupled plasma nitridation (DPN) chamber. Examples of such DPN process chambers include DPN Centura™ chamber, commercially available from Applied Materials, Inc., Santa Clara, Calif. One example of a processing chamber that may be used to perform a decoupled plasma nitridation process is described in commonly assigned U.S. Ser. No. 10/819,392, filed Apr. 6, 2004, and published as U.S. 20040242021, which is herein incorporated by reference in its entirety. In another aspect of the invention, one or more of the substrate processing chambers 201-204 may be a metal etch or dielectric etch chamber. Examples of such metal and dielectric etch chambers include the Centura™ AdvantEdge Metal Etch chamber and Centura™ eMAX chamber, which are commercially available from Applied Materials, Inc., Santa Clara, Calif.

Referring to FIG. 2 and as noted above, the processing chambers 201-204 mounted in one of the positions 114A-D may perform any number of processes, such as a PVD, a CVD (e.g., dielectric CVD, MCVD, MOCVD, EPI), an ALD, a decoupled plasma nitridation (DPN), a rapid thermal processing (RTP), or a dry-etch process to form various device features on a surface of the substrate. The various device features may include, but are not limited to the formation of interlayer dielectric layers, gate dielectric layer, polysilicon gates, forming vias and trenches, planarization steps, and depositing contact or via level interconnects. In one embodiment, the positions 114E-114F contain service chambers 116A-B that are adapted for degassing, orientation, cool down and the like. In one embodiment, the processing sequence is adapted to form a high-K capacitor structure, where processing chambers 201-204 may be a DPN chamber, a CVD chamber capable of depositing poly-silicon, and/or a MCVD chamber capable of depositing titanium, tungsten, tantalum, platinum, or ruthenium. In another embodiment, the processing sequence is adapted to form a gate stack, where processing chambers 201-204 may be a DPN chamber, a CVD chamber capable of depositing a dielectric material, a CVD chamber capable of depositing poly-silicon, an RTP chamber and/or a MCVD chamber.

Referring to FIG. 2, an optional front-end environment 104 (also referred to herein as a Factory Interface or FI) is shown positioned in selective communication with a pair of load lock chambers 106. Factory interface robots 108A-B disposed in the transfer region 104B of the front-end environment 104 are capable of linear, rotational, and vertical movement to shuttle substrates between the load lock chambers 106 and a plurality of pods 105 which are mounted on the front-end environment 104. The front-end environment 104 is generally used to transfer substrates from a cassette (not shown) seated in the plurality of pods 105 through an atmospheric pressure clean environment/enclosure to some desired location, such as a process chamber. The clean environment found in the transfer region 104B of the front-end environment 104 is generally provided by use of an air filtration process, such as passing air through a high efficiency particulate air (HEPA) filter, for example. A front-end environment, or front-end factory interface, is commercially available from Applied Materials Inc. of Santa Clara, Calif.

A robot 113 is centrally disposed in the transfer chamber 110 to transfer substrates from the load lock chambers 106A or 106B to one of the various processing chambers mounted in positions 114A-F. The robot 113 generally contains a blade assembly 113A, arm assemblies 113B which are attached to the robot drive assembly 113. The robot 113 is adapted to transfer the substrate “W” to the various processing chambers by use of commands sent from the system controller 102. A robot assembly that may be adapted to benefit from the invention is described in commonly assigned U.S. Pat. No. 5,469,035, entitled “Two-axis magnetically coupled robot”, filed on Aug. 30, 1994; U.S. Pat. No. 5,447,409, entitled “Robot Assembly” filed on Apr. 11, 1994; and U.S. Pat. No. 6,379,095, entitled Robot For Handling Semiconductor Substrates”, filed on Apr. 14, 2000, which are hereby incorporated by reference in their entireties.

The load lock chambers 106 (e.g., load lock chambers 106A and 106B) provide a first vacuum interface between the front-end environment 104 and a transfer chamber 110. In one embodiment, two load lock chambers 106A and 106B are provided to increase throughput by alternatively communicating with the transfer chamber 110 and the front-end environment 104. Thus, while one load lock chamber 106 communicates with the transfer chamber 110, a second load lock chamber 106 can communicate with the front-end environment 104. In one embodiment, the load lock chambers 106 are a batch type load lock that can receive two or more substrates from the factory interface, retain the substrates while the chamber is sealed and then evacuated to a low enough vacuum level to transfer of the substrates to the transfer chamber 110. Preferably, the batch load locks can retain from 25 to 50 substrates at one time.

The system controller 102 is generally designed to facilitate the control and automation of the overall system and typically may includes a central processing unit (CPU) (not shown), memory (not shown), and support circuits (or I/O) (not shown). The CPU may be one of any form of computer processors that are used in industrial settings for controlling various system functions, chamber processes and support hardware (e.g., detectors, robots, motors, gas sources hardware, etc.) and monitor the system and chamber processes (e.g., chamber temperature, process sequence throughput, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 102 determines which tasks are performable on a substrate. Preferably, the program is software readable by the system controller 102 that includes code to perform tasks relating to monitoring, control and execution of the processing sequence tasks and various chamber process recipe steps.

Support Chamber Configuration

In one embodiment, the cluster tool 100 contains a system controller 102, a plurality of substrate processing chambers 201-204 and one or more support chambers 211. In general, a support chamber may be a metrology chamber, a preprocessing chamber, or a post-processing chamber. The addition of a support chamber may be added to the cluster tool 100 for a number of reasons, which include, but are not limited to improving device yield, improving process repeatability from substrate to substrate, analyzing the process results, and reducing the effect of queue time differences between substrates.

In one aspect, as illustrated in FIG. 2, two support chambers 211 are mounted in the positions 214A or 214B with in the transfer chamber 110. Filling the unused space within the transfer chamber 110 with one or more support chambers 211 will help to reduce the system cost and CoO by reducing the number of additional hardware required to add the support chamber components, reducing the overhead time required to transfer substrates between the cluster tool process chambers and the support chamber 211, and reducing the cluster tool footprint.

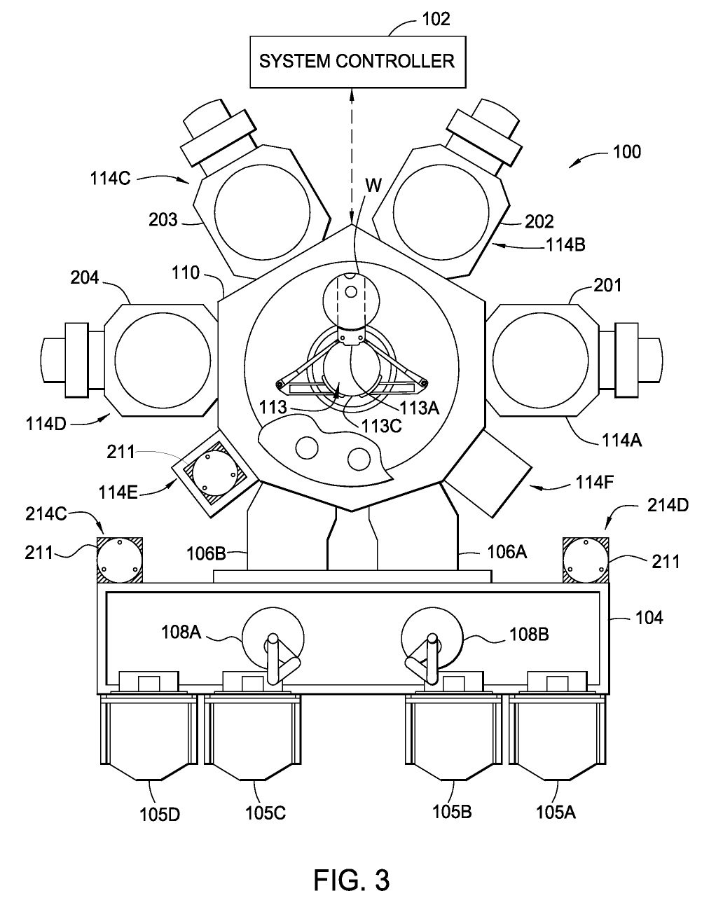

FIG. 3 illustrates another configuration of the cluster tool 100 in which the support chambers 211 are placed in other regions of the cluster tool 100, such as being mounted in the position 114E and/or positions 214C or 214D that are attached to a front-end environment 104. It should be noted that it may be desirable to mount the support chamber 211 in one or more of positions 114A-114F, positions 214A-D or any other convenient positions that is accessible by one or more of the cluster tool robotic devices.

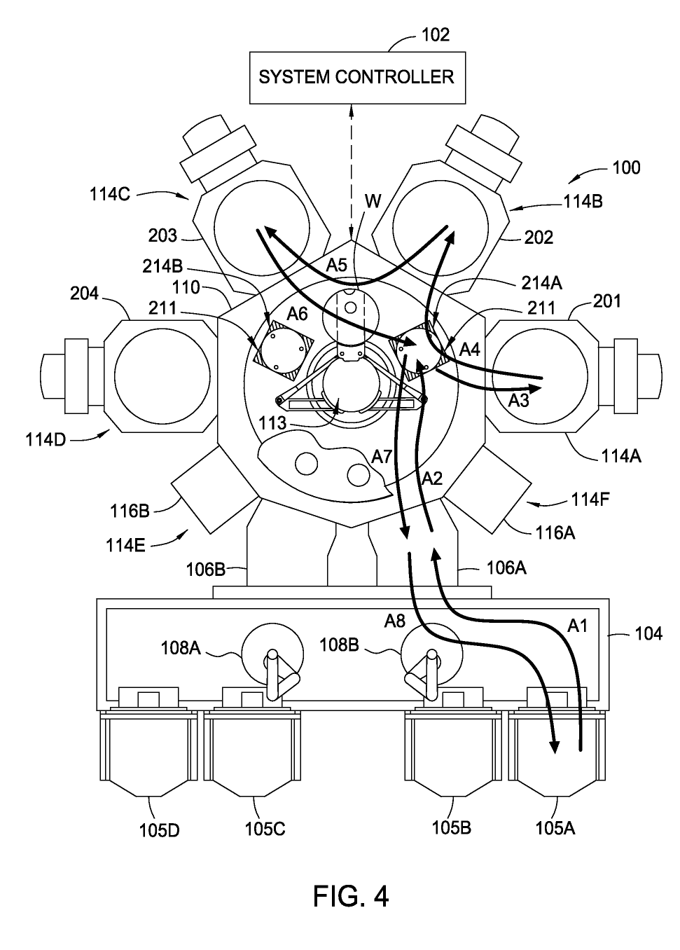

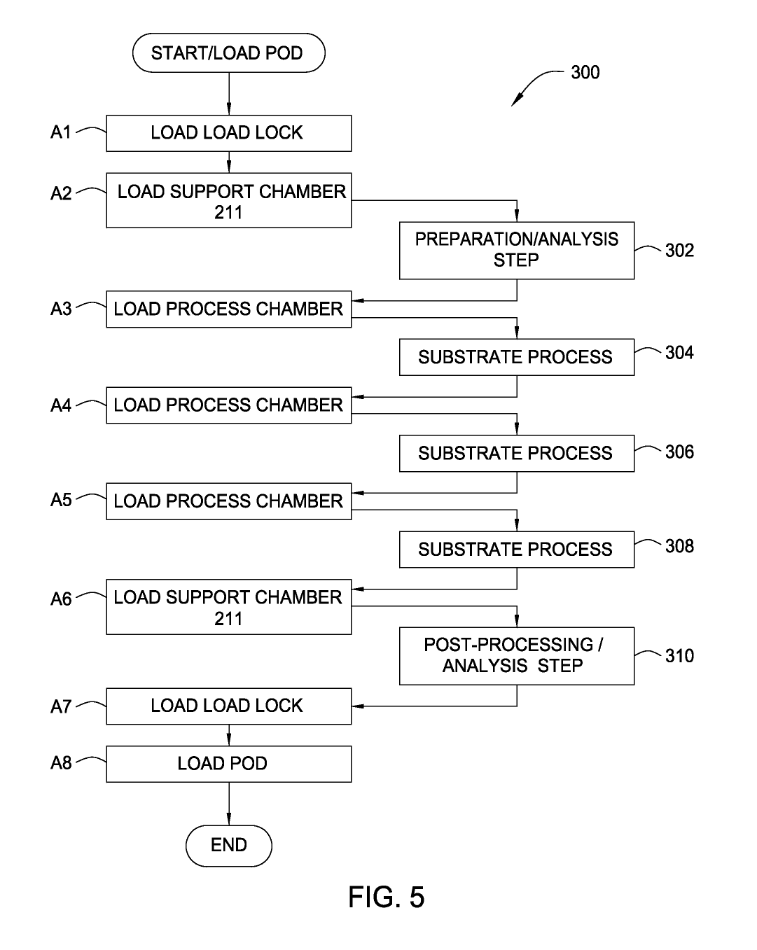

An example of processing sequence performed in a representative cluster tool configuration that includes the use of a support chamber 211 is illustrated in FIGS. 4 and 5. FIG. 4 illustrates the movement of a substrate “W” through the cluster tool 100 following the processing steps described in FIG. 5. Each of the arrows labeled A1 through A8 in FIG. 4 illustrates the movement of the substrates, or transfer paths, within the cluster tool 100. In this configuration, the substrate is removed from a pod placed in the position 105A and is delivered to load lock chamber 106A following the transfer path A1. The system controller 102 then commands the load lock chamber 106A to close and pump down to a desirable base pressure so that the substrates can be transferred into the transfer chamber 110 which is already in a vacuum pumped down state. The substrate is then transferred along path A2 where a preparation/analysis step 302 is performed on the substrate. The preparation/analysis step 302 may encompass one or more preparation steps including, but not limited to substrate inspection/analysis and/or particle removal. After completing preparation/analysis step 302 the substrate is then transferred to a processing chamber in position 114A, as shown in FIG. 4, following the transfer path A3, where the substrate process step 304 is performed on the substrate. After performing the substrate process step 304 the substrates are sequentially transferred to the substrate processing chambers 202 and 203 following the transfer paths A4-A5 where their respective substrate process steps 306 through 308, as shown in FIGS. 4 and 5. In one embodiment substrate process step 304 is a preclean processing step (discussed below). In one embodiment, substrate process steps 306 and 308 may be selected from one of the following group of processes oxide etch, metal etch, EPI, RTP, DPN, PVD, CVD (e.g., CVD polysilicon, TEOS etc.), or other suitable substrate processing step. The substrate is then transferred along path A6 where an associated post-processing/analysis step 310 is performed on the substrate. The post-processing/analysis step 310 may encompass one or more preparation steps including, but not limited to substrate inspection/analysis and/or particle removal step. After completing post-processing/analysis step 310 the substrate is then transferred to the load lock chamber 106A, following the transfer path A7. The load lock is then vented and the substrate is then removed from load lock and placed in the pod placed in position 105A following the transfer path A8.

Other embodiments of a process sequence may also include scenarios where the support chamber 211 is placed between at least one of the other processing steps in the processing sequence. In another embodiment, there is only one processing step completed on the substrate after the preparation/analysis step 302 or the post-processing/analysis step 310.

Particle/Contamination Removal Support Chamber(s)

In one embodiment, the support chamber 211 is configured to reduce the number of particles or amount of contamination on the surface of the substrate during the preparation/analysis step 302 and/or post-processing/analysis step 310 so that the device yield and substrate scrap can be improved for devices formed using a desired processing sequence. Generally, the particle/contamination reduction chamber, hereafter particle reduction chamber, exposes one or more surfaces of a substrate to ultraviolet (UV) radiation to impart enough energy to the particles and other contaminants on the surface of the substrate to cause them to move off of the surface of the substrate (e.g., Brownian motion), change the contaminants bonding characteristics to the exposed surface, or to causes the contaminants to vaporize. In operation, UV radiation, or UV light, at wavelengths between about 120 and about 430 nanometers (nm) at a power density between about 5 and about 25 mWatts/cm² may be delivered to a surface of the substrate from a radiation source contained with the particle/contamination reduction chamber. The radiation from the radiation source may be supplied by a lamp containing elements, such as xenon, argon, krypton, nitrogen, xenon chloride, krypton fluoride, argon fluoride. The use of a radiation source that emits UV light may be especially useful for removing or reducing the detrimental effect of organic contamination found on the substrate surface. A typical radiation source that is adapted to emit UV wavelengths may be a conventional UV lamp (e.g., mercury vapor lamp) or other similar device. Combinations of UV emitting radiation sources that emit UV light at different wavelengths may also be used.

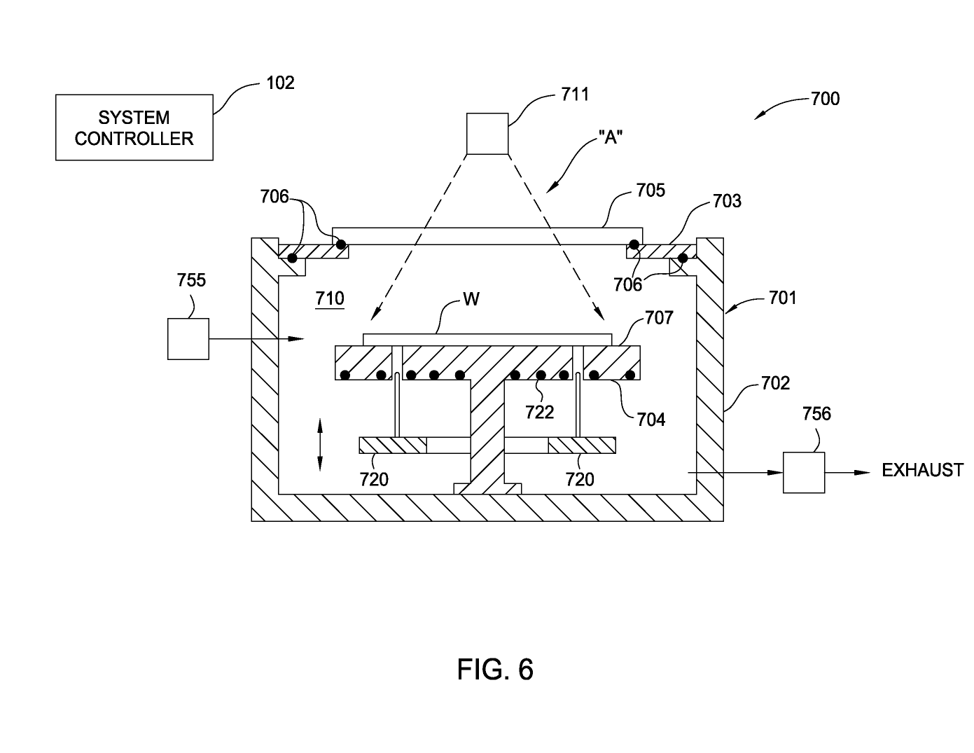

FIG. 6 illustrates is a cross-sectional side view of a type of support chamber 211 that is a particle reduction chamber 700 which exposes one or more surfaces of a substrate to ultraviolet (UV) radiation. The particle reduction chamber 700 may be mounted in any available position in a cluster tool, such as positions 114A-114F (FIG. 2) or positions 214A-214E (FIG. 3). In general, the particle reduction chamber 700 will contain an enclosure 701, a radiation source 711 and a substrate support 704. The enclosure 701 generally contains a chamber body 702, a chamber lid 703 and a transparent region 705. In one aspect, the enclosure 701 contains one or more seals 706 that seal the processing region 710, so that it can be pumped down a vacuum condition during processing by a vacuum pump 736. In one aspect, the processing region 710 is pumped down and maintained at a pressure between about 10⁻⁶ Torr and about 700 Torr by use of the vacuum pump 736 and a gas delivery source 735. In one embodiment, the processing region 710 is maintained at or near atmospheric pressure by continually delivering an inert gas to the processing region 710 from the gas delivery source 735. The transparent region 705, may be made of a ceramic, glass or other material that is optically transparent to the radiation being emitted from the radiation source 711 so that the substrate “W” can receive the bulk of the energy emitted from the radiation source 711. In one aspect, the particle reduction chamber 700 may contain a lift assembly 720 that is adapted to raise and lower the substrate “W” relative to the substrate support 704 so that a robotic device (not shown) can pickup and drop off substrate on the lift assembly 720.

In one embodiment, the substrate support 704 is adapted to heat the substrate during the particle removal step to further increase the efficiency of removing particle from the surface of the substrate by adding energy to the contaminants to cause them to move from the surface of the substrate or vaporize during the particle reduction process. In this configuration, the substrate support 704 may be heated by use of a heating element 722 that is embedded within the substrate support 704 and an external power supply/controller (not shown) so that the substrate supporting surface 707 can be heated to a desired temperature. In one embodiment, the substrate support 704 is heated by use of conventional infrared lamps to a desired temperature. In one aspect, the substrate support 704 is heated to a temperature between about 250° C. and about 850° C., and more preferably between about 350° C. and about 650° C. In one aspect, it may be desirable to deliver the substrate to the particle reduction chamber 700 and the substrate support 704 while the substrate is still at a temperature between 250° C. and about 550° C., due to the heat added to the substrate during the prior processing steps in the processing sequence.

Metrology Chamber Configurations

In one embodiment, the support chamber 211 is a metrology chamber that is adapted to perform the preparation/analysis step 302 and/or the post-processing/analysis step 310 to analyze a property of the substrate before or after performing a processing step in a processing sequence. In general, the properties of the substrate that can be measured in the metrology chamber may include, but is not limited to the measurement of the intrinsic or extrinsic stress in one or more layers deposited on a surface of the substrate, film composition of one or more deposited layers, the number of particles on the surface of the substrate, and the thickness of one or more layers found on the surface of the substrate. The data collected from the metrology chamber is then used by the system controller 102 to adjust one or more process variables in one or more of the processing steps to produce favorable process results on subsequently processed substrates. An example of a metrology chamber hardware and control algorithms that may be adapted to measure and analyze particles found on a surface of a substrate can be found in the commonly assigned U.S. patent application Ser. Nos. 6,630,995, 6,654,698, 6,952,491 and 6,693,708, which are incorporated by reference herein in their entirety.

Film Analysis Chamber

In one embodiment, the support chamber 211 is a metrology chamber that is adapted to measure the composition and thickness of a deposited film on the surface of the substrate by use of conventional optical measurement techniques. Typical composition and thickness measurement techniques include conventional ellipsometry, reflectometry or x-ray photoelectron spectroscopy (XPS) techniques. The composition and thickness results measured at desired regions on the surface of the substrate using these techniques are then fed back to the system controller 102, so that adjustments can be made to one or more of the upstream or downstream process steps in a processing sequence.

The substrate composition and thickness results can thus be stored and analyzed by the system controller 102 so that one or more of the process variables can be varied to improve the process results achieved on subsequently processed substrates and/or correct deficiencies in the already processed substrates by adjusting the process parameters of processes performed downstream of the support chamber 211. In one example, a composition or thickness analysis is performed after an EPI layer is deposited on a surface of the substrate so that the process variables (e.g., RF power, process pressure, gas flow rate, film thickness, deposition rate) can be adjusted to correct for undesirable process results in subsequent EPI deposition processes.

Ellipsometry is a non-invasive optical technique for determining film thickness, interface roughness, and composition of thin surface layers and multilayer structures. The method measures the change in the state of polarization of light upon reflection from the sample surface to determine the conventional ellipsometry parameters (e.g., amplitude change (ψ), phase shift (Δ)). These optical parameters can then be matched to computer models or stored data within the system controller 102 to determine the structure and composition of the sample at the region on the surface of the substrate.

Reflectometry is an analytical technique for investigating thin layers using the effect of total external reflection of optical radiation. In reflectivity analysis techniques, the reflection of the optical radiation from a sample is measured at different angles is measured so that the thickness and density, surface roughness can be determined. These reflectometry results can then be matched to computer models or stored data within the system controller 102 to determine the structure and composition of the sample at the region on the surface of the substrate.

X-ray photoelectron spectroscopy (XPS) tools can be used to measure the elemental composition, chemical state and electronic state of the elements that exist within a material. XPS spectra are obtained by irradiating a material with a beam of X-rays while simultaneously measuring the kinetic energy and number of the electrons that escape from the material being analyzed using conventional measurement techniques. These XPS results can then be matched to computer models or stored data within the system controller 102 to determine the structure and composition of the sample at the region on the surface of the substrate.

In one embodiment, a pattern recognition system is used in conjunction with the one or more analysis steps performed in a support chamber 211 to provide analysis and feed back regarding the state of selected regions on the surface of the substrate. In general, the pattern recognition system uses an optical inspection technique that is scans a surface of the substrate and compares the received data from the scan with data stored within a controller so that the controller can decide where on the surface of the substrate the measurement is to be made. In one embodiment, the pattern recognition system contains a controller (e.g., controller 102 (FIG. 2)), a conventional CCD camera and a stage that is adapted to move a substrate positioned thereon relative to the CCD camera. During processing data stored within the memory of the controller is compared with the data received from the CCD camera as it passes over the surface of the substrate so that desirable test regions on the surface of the substrate can be found and then analyzed by the components in the metrology chamber.

Substrate Bow Stress Measurement Analysis Chamber

In another embodiment, the support chamber 211 is adapted to measure the stress, or strain, contained within a deposited film on the surface of the substrate by use of conventional substrate bow measurement techniques. It should be noted that it is generally possible to calculate the stress and strain contained within a region of the substrate by measuring one parameter (e.g., stress or strain), measuring or knowing the type of material contained within measurement region and/or one or more material properties. A conventional stress, or strain, measurement tool that measures the bow, or the change in bow, of a substrate during the process sequence is configured to measure the stress, or strain, in the substrate after performing one or more processing steps in the processing sequence and then feeds back the results to the system controller 102 so that the system controller 102 can decide what actions need to be taken in one or more process steps in the processing sequence. A conventional stress measurement tool that may be adapted to measure the stress of the substrate may be available from KLA-Tencor corporation, Nanometrics, Inc. or Therma-Wave, Inc.

In one example, it may be desirable to measure the stress, or strain, of an EPI layer that was formed in a prior deposition processing step and feed back the data to a system controller 102 which can then make decisions as to how to improve the process results achieved on subsequently processed substrates or even make adjustments to downstream processes to resolve the problem noted in from the measurement of stress, or strain, in the substrate. The system controller 102 uses the substrate bow results to adjust one or more of the process variable (e.g., RF power, process pressure, film thickness, deposition rate), to improve the process results of on the surface of the subsequent substrates.

XRD Metrology Chamber

In one embodiment, a metrology chamber integrated into the cluster tool 100 utilizes an x-ray diffraction (XRD) technique to measure the film thickness, film composition and film stress, or strain. Typical XRD techniques utilize Bragg's Law to help analyze and interpret the diffraction patterns generated when exposing one or more regions on the surface of the substrate to the emitted x-ray radiation. In general, the XRD chamber contains an x-ray source, one or more radiation detectors, a substrate support, and an actuator that can articulate the x-ray source relative to the substrate, or the substrate support relative to the x-ray source, so that a diffraction pattern can be generated and analyzed. The results obtained from an XRD type metrology chamber can be used to measure various characteristics of the film(s) on the surface of the substrate prior to or after performing one or more of the process sequence processing steps. By use of the system controller 102 the results received from the XRD chamber can be used to adjust process variables in the various process steps to improve the results achieved from the processing sequence. In one example, it may be desirable to measure the stress of an EPI layer that was formed in a prior deposition processing step. Therefore, by use of the system controller 102 the XRD results can be used to adjust one or more of the EPI process variable (e.g., RF power, process pressure, film thickness, deposition rate), to improve the process results. A metrology chamber that has the ability to characterize multiple different characteristics of the film (e.g., stress, film composition, thickness) at different stages of the processing sequence, such as an XRD chamber, is useful to reduce the system cost, reduce the system footprint, improve the reliability of the cluster tool, and reduce the overhead time required to transfer substrates between chambers versus a configuration that uses separate metrology chambers to perform the analyses.

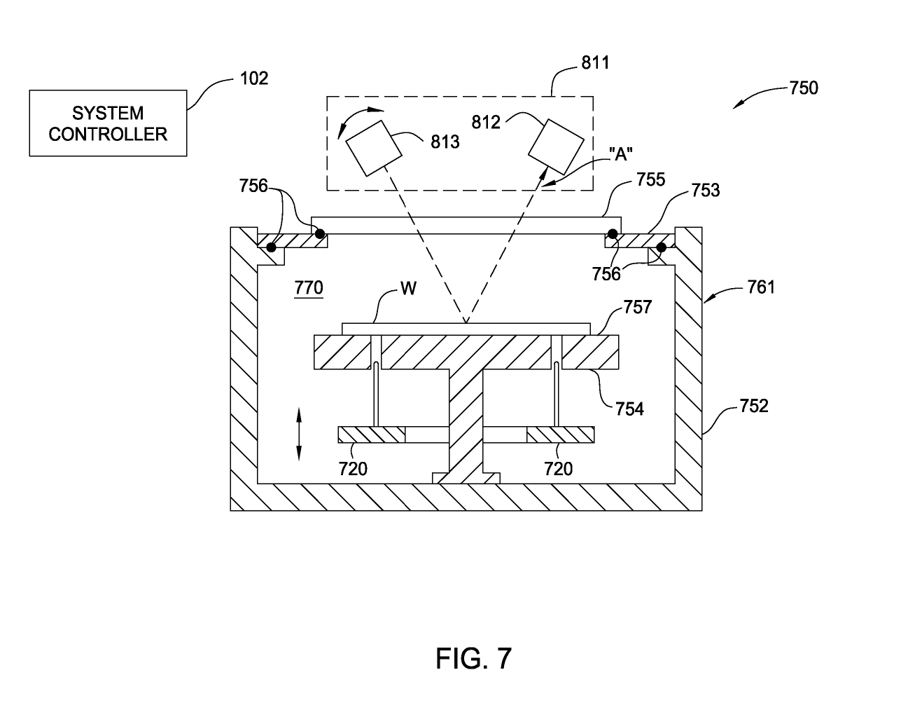

FIG. 7 illustrates a cross-sectional side view of a type of support chamber 211, or metrology chamber 750 that can be used to analyze a property of the substrate before or after performing a processing step in a processing sequence (e.g., processing sequences 300 and processing sequence 301A-301B discussed below). The metrology chamber 750 may be mounted in any available position in a cluster tool, such as positions 114A-114F (FIG. 2) or positions 214A-214E (FIG. 3). In general, the metrology chamber 750 will contain an enclosure 761, a measurement assembly 811 and a substrate support 754. The substrate support 754 has a substrate supporting surface 757. The enclosure 761 generally contains a chamber body 752, a chamber lid 753 and a transparent region 755. In one aspect, the enclosure 751 contains one or more seals 756 that seal the processing region 770, so that it can be pumped down a vacuum condition during processing by a vacuum pump (not shown). In one aspect, the processing region 770 is pumped down to a pressure between about 10⁻⁶ Torr and about 700 Torr. The transparent region 755, may be made of a ceramic, glass or other material that is optically transparent to the radiation being emitted from a source 813 contained within the measurement assembly 811. In one embodiment, the radiation emitted from the source 813 passes through the transparent region 755 strikes a surface of the substrate, where it is reflected and then passes back through the transparent region 755 where it is collected by a sensor 812 contained in the measurement assembly 811. In one aspect, the metrology chamber 750 contains a lift assembly 720 that is adapted to raise and lower the substrate “W” relative to the substrate support 754 so that a robotic device (not shown) can transfer substrates between the metrology chamber 750 and other processing chambers within the cluster tool.

Integrated Support Chamber

FIG. 8 is a side cross-sectional view of a transfer chamber 110 that contains a support chamber assembly 800, which is contained within support chamber 211 that may be adapted to perform a metrology process, a preprocessing process step, or a post-processing process step. In one embodiment, as shown in FIG. 8, the support chamber assembly 800 is configured to reduce the number of particles on the surface of the substrate during the preparation/analysis step 302 and/or post-processing/analysis step 310. The support chamber assembly 800 generally contains all of the components found in the particle reduction chamber 700, discussed above, except the enclosure 701 components, such as the chamber body 702 and chamber lid 703 are replaced with the transfer chamber base 110B and the transfer chamber lid 110A, respectively.

In one embodiment, the substrate support 704 and lift assembly 720 are positioned within the transfer region 110C and mounted to the transfer chamber base 110B of the transfer chamber 110, and thus adjacent to one or more of the processing chambers (e.g., process chamber 201 is shown in FIG. 8). In this configuration, the radiation source 711 is attached to the support 808 that is mounted to transfer chamber lid 110A so that the radiation emitted from the radiation source 711 passes through the transparent region 705 and strikes a substrate W positioned on the substrate supporting surface 707 of the substrate support 704. The system controller 102 and an actuator (not shown) contained within the lift assembly 720 can be used to transferred a substrate “W” between the robot blade assembly 113A and the substrate support 704. The support chamber assembly 800 is generally configured to prevent collisions between the robot 113 and any of the components in the support chamber assembly 800 during normal transferring operations completed by the robot 113.

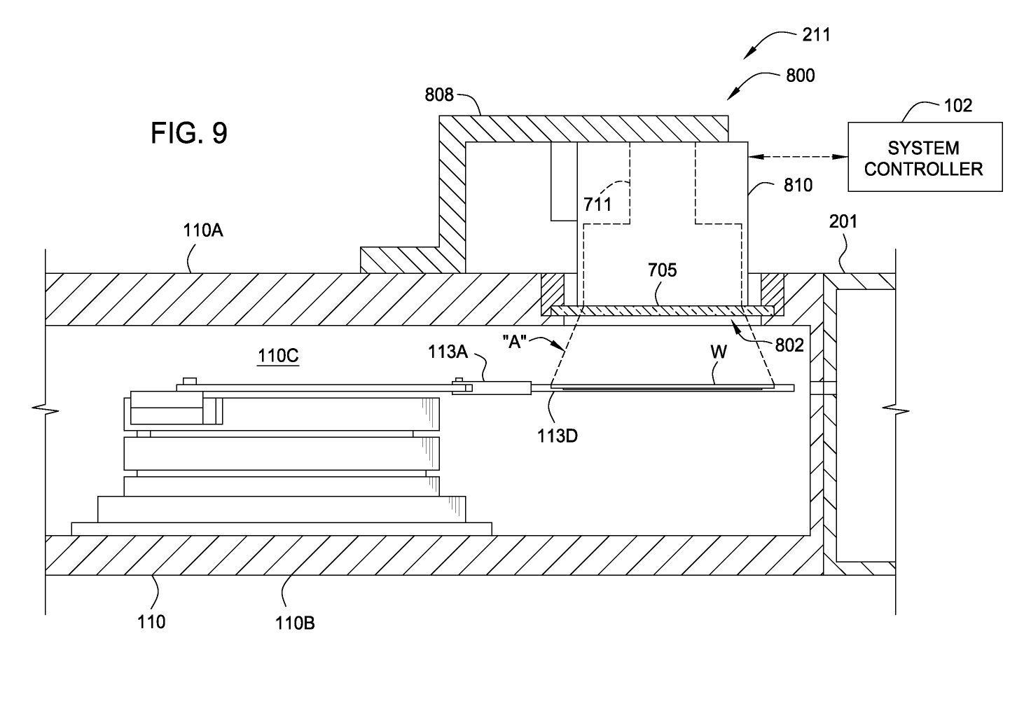

FIG. 9 is a side cross-sectional view of one embodiment of the support chamber assembly 800 that is positioned on a portion of the transfer chamber 110 so that a particle reduction step, discussed above, can be performed while the substrate W is positioned on the robot blade assembly 113A of the robot 113. In one embodiment, the substrate W is positioned below the radiation source 711 that is mounted on the transfer chamber lid 110A so that the emitted radiation from the radiation source 711 can strike a surface of the substrate as the substrate passes underneath the support chamber assembly 800 during the process of transferring a substrate through the cluster tool 100. In another embodiment, the system controller 102 and robot 113 are adapted to position and hold the robot blade assembly 113A and substrate W under the radiation source 711 for a desired period of time during the transferring sequence so that the particle removal process can be performed on the substrate.

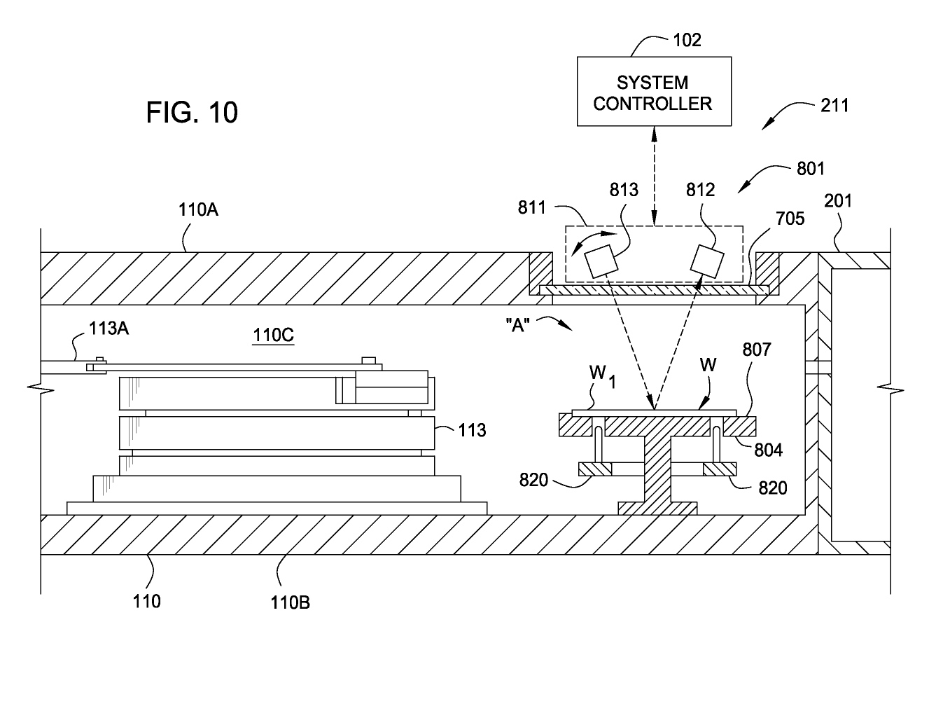

FIG. 10 is a side cross-sectional view of a transfer chamber 110 that contains a support assembly 801, which is contained within the support chamber 211, that are adapted to perform the preparation/analysis step 302 and/or the post-processing/analysis step 310 to analyze a property of the substrate before or after performing a processing step in the processing sequence. In one embodiment, the support chamber assembly 801, is an XRD, XPS, stress measurement tool, reflectometer, or ellipsometer type tool that is configured to measure a property of substrate by exposing the substrate W to radiation emitted from a source 813 and then receiving a portion of the signal in a sensor 812. The results received by the support chamber assembly 801 are then communicated to the system controller 102 so that the system controller 102 can adjust one or more the process variable in the process sequence to improve the process results achieved in the system.

The support chamber assembly 801 generally contains a substrate support 804 and lift assembly 820 that are positioned within the transfer region 110C and mounted to the transfer chamber base 110B of the transfer chamber 110. In one aspect, the support chamber assembly 801 is positioned adjacent to one or more of the processing chambers (e.g., processing chamber 201 is shown in FIG. 10). In this configuration, the measurement assembly 811 is attached to the transfer chamber lid 110A and can view the processing surface W₁ of the substrate W positioned on the substrate supporting surface 807 of the substrate support 804 through the transparent region 705 that is sealably attached to the chamber lid 110A. The system controller 102 and an actuator (not shown) contained within the lift assembly 820 can be used to transferred a substrate “W” between the robot blade assembly 113A and the substrate support 804. The support chamber assembly 801 is generally designed and configured so that the robot 113 and any of the components in the support chamber assembly 801 will not collide with each other during normal transferring operations completed by the robot 113.

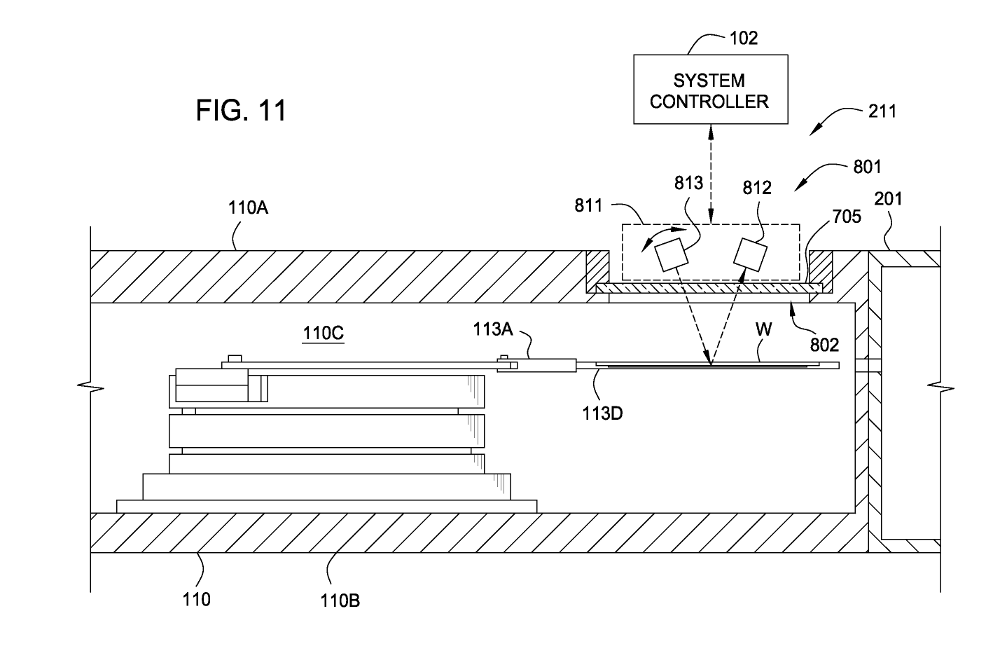

FIG. 11 is a side cross-sectional view of one embodiment of the support chamber assembly 801 that is positioned on the transfer chamber 110 so that the preparation/analysis step 302 and/or the post-processing/analysis step 310, discussed above, can be performed while the substrate W is positioned on the robot blade assembly 113A of the robot 113. In one embodiment, the substrate W is positioned so that the radiation emitted from a source 813 is received by a sensor 812 as the substrate passes underneath the support assembly 801 during the process of transferring a substrate through the cluster tool 100. In another embodiment, the system controller 102 and robot 113 are adapted to position and hold the robot blade assembly 113A and substrate W so that the support assembly 801 can perform an analysis on one or more regions of the substrate.

In one embodiment, not shown, the support chamber assembly 800 and the support chamber assembly 801 are integrated into one complete assembly that is mounted in mounted in any available position in a cluster tool, such as positions 114A-114F (FIG. 2) or positions 214A-214E (FIG. 3). In one embodiment, the support chamber assembly 801 and/or the support chamber assembly 801 are integrated into at least one of the load lock chambers 106A-106B (FIG. 2 or 3).

Queue Time Issues and Cluster Tool Configurations

In one embodiment, the cluster tool 100 contains a preparation chamber that is adapted to perform one or more preclean steps that prepare a surface on a substrate for subsequent device fabrication process steps. Preclean steps are generally important in the stages of semiconductor device fabrication where the length of time between processing steps, or queue time, is critical or the length of exposure to atmospheric, or other contamination sources, affects the fabricated device yield, fabricated device repeatability, and overall device performance. In one example, the queue time issue is created by the amount contamination found on a surface of a substrate due to the time dependent exposure to organic type contaminants that typically out-gas from the cassettes, FOUPs or other substrate handling components. In another example, the queue time issue is created by the native oxide growth that is formed prior to forming one or more of the contact level features, which thus affects the formed device performance of different substrates in a batch. To reduce the detrimental effect of native oxide growth on a formed semiconductor device, the native oxide layer is removed just prior to performing the next processing step, such as a metal oxide semiconductor (MOS) device gate oxide formation step. Performing the preparation steps thus assures that each substrate processed in the cluster tool starts at the same starting point prior to processing substrates in the cluster tool and thus makes the process results more repeatable. The preparation step thus effectively removes the effect of atmospheric contamination exposure time differences between the first substrate and the last substrate in a batch and the differences between one batch of substrates to another batch of substrates.

In one embodiment, the system controller 102 is adapted to monitor and control the queue time of the substrates processed in the cluster tool 100. Minimizing the queue time after a substrate is processed in a first processing chamber and before it is processed in the next processing chamber, will help to control and minimize the effect of the exposure to the contamination sources on device performance. This embodiment may be especially advantageous when used in conjunction with the inspection/analysis and particle/contamination removal steps and other embodiments described in conjunction with FIGS. 2-11, since the use of the analysis and/or particle/contamination removal steps can be used to further optimize one or more of the substrate processing step within a process sequence that utilizes a preclean process step and one or more substrate processing steps (e.g., PVD, CVD, EPI, dry etch). In one aspect, the analysis and/or particle/contamination removal steps can be used to further optimize the preclean process recipe. In one aspect of the invention the system controller 102 controls the timing of when a process recipe step is started or ended to increase the system throughput and reduce any queue time issues.

The preclean steps discussed herein may prepare a surface of a substrate by using wet chemical processes and/or plasma modification processes. Two examples of exemplary processes and hardware that may be used to perform one or more of the preparation steps are described below.

Plasma Preclean Chamber Configuration

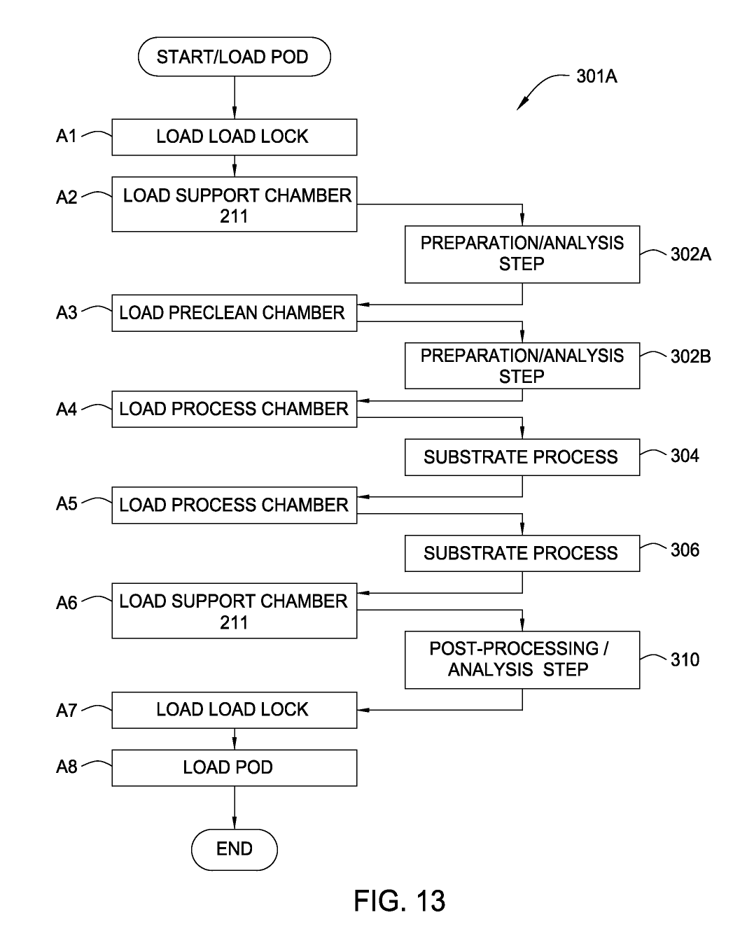

In one embodiment, the preparation/analysis step 302B in the processing sequence 301A, illustrated in FIG. 13, utilizes a plasma assisted type preclean processing step to remove a native oxide layer and other contaminants formed on a surface of a substrate prior to this step. Since the presence of a native oxide layers and other contaminants on the surface of the substrate will dramatically affect the device yield and process repeatability results one or more steps preclean steps may be performed on the substrate.

FIG. 13 illustrates an exemplary process sequence 301A that may perform a preclean process step in the cluster tool 100 (FIG. 4). FIG. 13 is similar to the process sequence 300 shown in FIG. 5 except that a preparation/analysis step 302B has been added so that the plasma-assisted preclean process can be performed on the substrate surface. In one embodiment, the process sequence 301A contains a preparation/analysis step 302A that is used to inspect and analyze characteristics of the substrate surface or perform a particle removal step that is followed by the preclean type preparation/analysis step 302B that is discussed below. In one aspect of the process sequence 301A, the substrate process step 304 and the substrate process step 306 may be selected from one of the following group of processes that include oxide etch, metal etch, EPI, RTP, DPN, PVD, CVD (e.g., CVD polysilicon, TEOS etc.), or other suitable semiconductor substrate processing step.

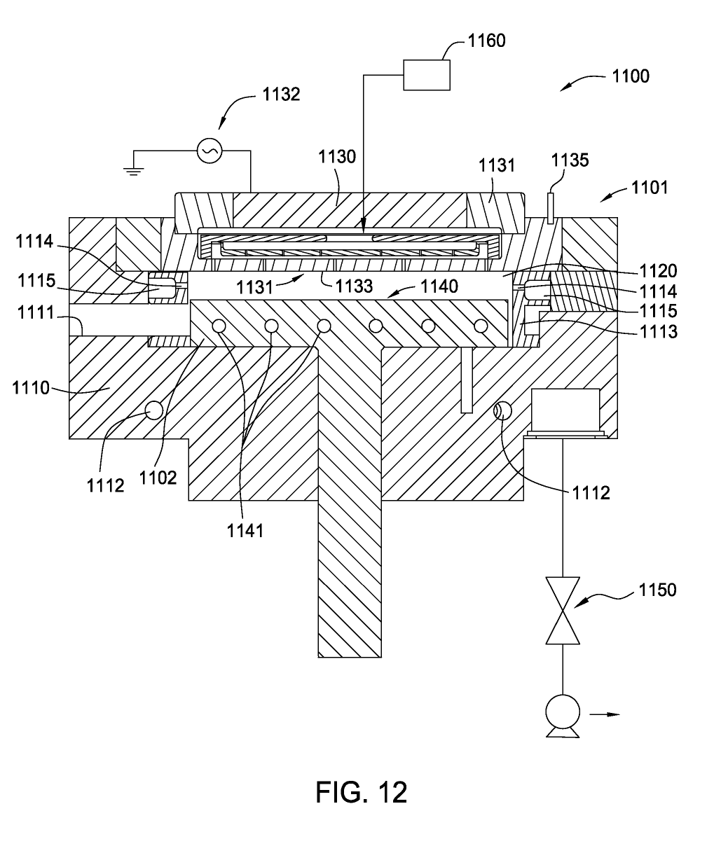

In one embodiment, the preparation/analysis step 302B treatment (hereafter preprocessing step) is performed in a preclean chamber 1100 (FIG. 12) that is adapted to perform an etching step and in-situ anneal step. A more detailed description of a preclean chamber and process that may be adapted to remove native oxide layers and other contaminants found on the substrate surface may be found in commonly assigned U.S. Patent Application Ser. No. 60/547,839 entitled “In-Situ Dry Clean Chamber For Front End Of Line Fabrication,” filed on Feb. 22, 2005, which is hereby incorporated by reference in its entirety to the extent not inconsistent with the claimed invention.

In one embodiment, the preclean chamber 1100 may perform a plasma-enhanced chemical etch process that utilizes both substrate heating and cooling all within a single processing environment, to perform the preprocessing step. FIG. 12 illustrates a partial cross sectional view of a preclean chamber 1100. The preclean chamber 1100 is a vacuum chamber containing a lid assembly 1101, a substrate support member 1102 which is temperature-controlled, a chamber body 1110 which is temperature-controlled, and a processing zone 1120. The processing zone 1120 is the region between the lid assembly 1101 and the substrate support member 1102. The substrate support member 1102 is generally adapted to support and control the temperature of the substrate during processing. The lid assembly 1101 contains a process gas supply panel (not shown) as well as a first and second electrode (elements 1130 and 1131) that define a plasma cavity for generating plasma external to the processing zone 1120. The process gas supply panel (not shown) is connected to the gas source 1160, which provides one or more reactive gases to the plasma cavity, through the second electrode 1131 and into the processing zone 1120. The second electrode 1131 is positioned over the substrate and adapted to heat the substrate after the plasma-assisted dry etch process is complete.

FIG. 12 is a partial cross sectional view showing an illustrative preclean chamber 1100. In one embodiment, the preclean chamber 1100 includes a chamber body 1110, a lid assembly 1101, and a support assembly 1140. The lid assembly 1101 is disposed at an upper end of the chamber body 1110, and the support assembly 1140 is at least partially disposed within the chamber body 1110. The chamber body 1110 includes a slit valve opening 1111 formed in a sidewall thereof to provide access to the interior of the preclean chamber 1100. The slit valve opening 1111 is selectively opened and closed to allow access to the interior of the chamber body 1110 by a substrate handling robot (e.g., robot 113 in FIG. 2).

In one or more embodiments, the chamber body 1110 includes a fluid channel 1112 formed therein for flowing a heat transfer fluid therethrough. The heat transfer fluid can be a heating fluid or a coolant and is used to control the temperature of the chamber body 1110 during processing and substrate transfer. The temperature of the chamber body 1110 is important to prevent unwanted condensation of the gas or byproducts on the chamber walls. Exemplary heat transfer fluids include water, ethylene glycol, or a mixture thereof. An exemplary heat transfer fluid may also include nitrogen gas.

The lid assembly 1101 generally includes a first electrode 1130 to generate a plasma that contains one or more reactive species within the lid assembly 1101 to perform one ore more of the preprocessing steps. In one embodiment, the first electrode 1130 is supported on the top plate 1131 and is electrically isolated therefrom. In one embodiment, the first electrode 1130 is coupled to a power source 1132 while the second electrode 1131 is connected to ground. Accordingly, a plasma containing one or more process gases is generated in the volumes between the first electrode 1130 and the second electrode 1131 as a process gases are delivered from a gas source 1160 through the holes 1133 formed in the top plate into the processing zone 1120.

A power source 1132 that is capable of activating the gases into reactive species and maintaining the plasma of reactive species can be used. For example, the power source 1132 may deliver energy in the form of radio frequency (RF), direct current (DC), or microwave (MW) power to the processing zone 1120. Alternatively, a remote activation source may be used, such as a remote plasma generator, to generate a plasma of reactive species which are then delivered into preclean chamber 1100. In one embodiment, the second electrode 1131 may be heated depending on the process gases and operations to be performed within the preclean chamber 1100. In one embodiment, a heating element 1135, such as a resistive heater for example, can be coupled to the second electrode 1131 or the distribution plate. Regulation of the temperature may be facilitated by a thermocouple coupled to the second electrode 1131 or the distribution plate.

The gas source 1160 is typically used to provide the one or more gases to the preclean chamber 1100. The particular gas or gases that are used depend upon the process or processes to be performed within the preclean chamber 1100. Illustrative gases can include, but are not limited to one or more precursors, reductants, catalysts, carriers, purge, cleaning, or any mixture or combination thereof. Typically, the one or more gases introduced to the preclean chamber 1100 flow into the lid assembly 1101 and then into the chamber body 1110 through the second electrode 1131. Depending on the process, any number of gases can be delivered to the preclean chamber 1100, and can be mixed either in the preclean chamber 1100 or before the gases are delivered to the preclean chamber 1100. The process gases found in the chamber body 1110 are then exhausted by the vacuum assembly 1150 through the apertures 1114 and pumping channel 1115 formed in the liner 1113.

The support assembly 1140 may be at least partially disposed within the chamber body 1110. The support assembly 1140 can include a substrate support member 1102 to support a substrate (not shown in this view) for processing within the chamber body 1110. The substrate support member 1102 can be coupled to a lift mechanism (not shown) which extends through a bottom surface of the chamber body 1110. The lift mechanism (not shown) can be flexibly sealed to the chamber body 1110 by a bellows (not shown) that prevents vacuum leakage from around the lift mechanism. The lift mechanism allows the substrate support member 1102 to be moved vertically within the chamber body 1110 between a process position and a lower, transfer position. The transfer position is slightly below slit valve opening 1111 formed in a sidewall of the chamber body 1110.

In one or more embodiments, the substrate support member 1102 has a flat, circular surface or a substantially flat, circular surface for supporting a substrate to be processed thereon. The substrate support member 1102 is preferably constructed of aluminum. The substrate support member 1102 can be moved vertically within the chamber body 1110 so that a distance between substrate support member 1102 and the lid assembly 1101 can be controlled. Substrate support member 1102 may include one or more bores (not shown) formed therethrough to accommodate a lift pin (not shown). Each lift pin is typically constructed of ceramic or ceramic-containing materials, and are used for substrate-handling and transport. In one or more embodiments, the substrate (not shown) may be secured to the substrate support member 1102 using an electrostatic or vacuum chuck. In one or more embodiments, the substrate may be held in place on the substrate support member 1102 by a mechanical clamp (not shown), such as a conventional clamp ring. Preferably, the substrate is secured using an electrostatic chuck.

The temperature of the support assembly 1140 is controlled by a fluid circulated through one or more fluid channels 1141 embedded in the body of the substrate support member 1102. Preferably, the fluid channel 1141 is positioned about the substrate support member 1102 to provide a uniform heat transfer to the substrate receiving surface of the substrate support member 1102. The fluid channel 1141 and can flow heat transfer fluids to either heat or cool the substrate support member 1102. Any suitable heat transfer fluid may be used, such as water, nitrogen, ethylene glycol, or mixtures thereof. The support assembly 1140 can further include an embedded thermocouple (not shown) for monitoring the temperature of the support surface of the substrate support member 1102.

In operation, the substrate support member 1102 can be elevated to close proximity of the lid assembly 1101 to control the temperature of the substrate being processed. As such, the substrate can be heated via radiation emitted from the lid assembly 1101 or the distribution plate, which are heated by heating element 1135. Alternatively, the substrate can be lifted off the substrate support member 1102 to close proximity of the heated lid assembly 1101 using the lift pins.

An exemplary dry etch process for removing native oxides on a surface of the substrate using an ammonia (NH₃) and nitrogen trifluoride (NF₃) gas mixture performed within a preclean chamber will now be described. The dry etch process begins by placing a substrate, such as a semiconductor substrate, into a preclean chamber. Preferably, the substrate is held to the support assembly 1140 of the substrate support member 1102 during processing via a vacuum or electrostatic chuck. The chamber body 1110 is preferably maintained at a temperature of between 50° C. and 80° C., more preferably at about 65° C. This temperature of the chamber body 1110 is maintained by passing a heat transfer medium through fluid channels 1112 located in the chamber body. During processing, the substrate is cooled below 65° C., such as between 15° C. and 50° C., by passing a heat transfer medium or coolant through fluid channels 1112 formed within the substrate support. In another embodiment, the substrate is maintained at a temperature of between 22° C. and 40° C. Typically, the substrate support is maintained below about 22° C. to reach the desired substrate temperatures specified above.

The ammonia and nitrogen trifluoride gases are then introduced into the preclean chamber to form a cleaning gas mixture. The amount of each gas introduced into the chamber is variable and may be adjusted to accommodate, for example, the thickness of the oxide layer to be removed, the geometry of the substrate being cleaned, the volume capacity of the plasma and the volume capacity of the chamber body 1110. In one aspect, the gases are added to provide a gas mixture having at least a 1:1 molar ratio of ammonia to nitrogen trifluoride. In another aspect, the molar ratio of the gas mixture is at least about 3 to 1 (ammonia to nitrogen trifluoride). Preferably, the gases are introduced in the dry etching chamber at a molar ratio of from 5:1 (ammonia to nitrogen trifluoride) to 30:1. More preferably, the molar ratio of the gas mixture is of from about 5 to 1 (ammonia to nitrogen trifluoride) to about 10 to 1. The molar ratio of the gas mixture may also fall between about 10:1 (ammonia to nitrogen trifluoride) and about 20:1.

A purge gas or carrier gas may also be added to the gas mixture. Any suitable purge/carrier gas may be used, such as argon, helium, hydrogen, nitrogen, or mixtures thereof, for example. Typically, the overall gas mixture is from about 0.05% to about 20% by volume of ammonia and nitrogen trifluoride. The remainder being the carrier gas. In one embodiment, the purge or carrier gas is first introduced into the chamber body 1110 before the reactive gases to stabilize the pressure within the chamber body. The operating pressure within the chamber body can be variable. Typically, the pressure is maintained between about 500 mTorr and about 30 Torr. Preferably, the pressure is maintained between about 1 Torr and about 10 Torr. More preferably, the operating pressure within the chamber body is maintained between about 3 Torr and about 6 Torr.

An RF power of from about 5 and about 600 Watts is applied to the first electrode to ignite a plasma of the gas mixture within the plasma cavity. Preferably, the RF power is less than 100 Watts. More preferable is that the frequency at which the power is applied is very low, such as less than 100 kHz. Preferably, the frequency ranges from about 50 kHz to about 90 kHz.

The plasma energy dissociates the ammonia and nitrogen trifluoride gases into reactive species that combine to form a highly reactive ammonia fluoride (NH₄F) compound and/or ammonium hydrogen fluoride (NH₄F.HF) in the gas phase. These molecules then flow through the second electrode 1131 to react with the substrate surface to be cleaned. In one embodiment, the carrier gas is first introduced into the preclean chamber, a plasma of the carrier gas is generated, and then the reactive gases, ammonia and nitrogen trifluoride, are added to the plasma.

Not wishing to be bound by theory, it is believed that the etchant gas, NH₄F and/or NH₄F.HF, reacts with the native oxide surface to form ammonium hexafluorosilicate (NH₄)₂SiF₆, NH₃, and H₂O products. The NH₃, and H₂O are vapors at processing conditions and removed from the chamber by a vacuum pump attached to the chamber. A thin film of (NH₄)₂SiF₆ is left behind on the substrate surface.

After performing the plasma processing step a thin film of (NH₄)₂SiF₆ is formed on the substrate surface, the substrate support is elevated to an anneal position in close proximity to the heated second electrode. The heat radiated from the second electrode 1131 should be sufficient to dissociate or sublimate the thin film of (NH₄)₂SiF₆ into volatile SiF₄, NH₃, and HF products. These volatile products are then removed from the chamber by the vacuum assembly 1150. Typically, a temperature of 75° C. or more is used to effectively sublimate and remove the thin film from the substrate. Preferably, a temperature of 100° C. or more is used, such as between about 115° C. and about 200° C.

The thermal energy to dissociate the thin film of (NH₄)₂SiF₆ into its volatile components is convected or radiated by the second electrode. A heating element 1135 is directly coupled to the second electrode 1131, and is activated to heat the second electrode and the components in thermal contact therewith to a temperature between about 75° C. and 250° C. In one aspect, the second electrode is heated to a temperature of between 100° C. and 150° C., such as about 120° C.

Once the film has been removed from the substrate, the chamber is purged and evacuated. The cleaned substrate is then removed from the chamber by lowering the substrate to the transfer position, de-chucking the substrate, and transferring the substrate through the slit valve opening 1111.

As noted in FIG. 13, after performing the preparation/analysis step 302B the substrate can then be processed using one or more substrate processing steps selected from one of the following group of processes that may include oxide etch, metal etch, EPI, RTP, DPN, PVD, CVD (e.g., CVD polysilicon, TEOS etc.), or other suitable semiconductor substrate processing step.

Wet Clean Type Preclean Chamber Configurations

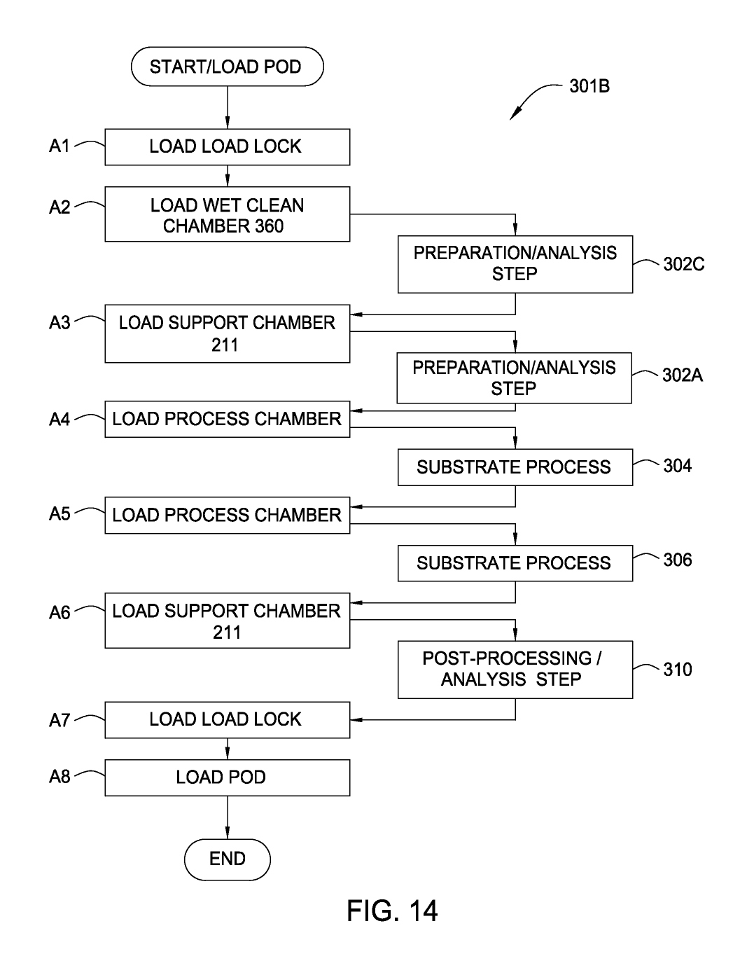

In another embodiment, a native oxide layer and other contaminants found on an exposed substrate surface are removed using a wet clean type preclean process, hereafter wet clean process, prior to performing one or more substrate device fabrication process steps in a processing sequence. FIG. 14 illustrates a process sequence 301B that can be used to improve device yield and process repeatability by performing one or more wet clean type preclean process steps.

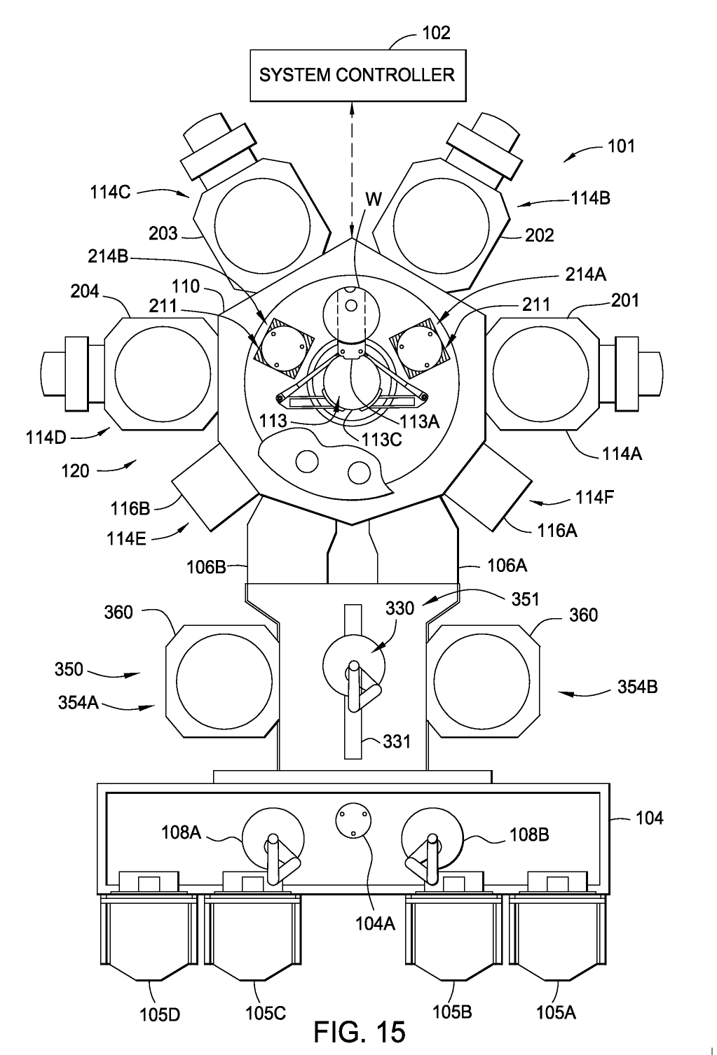

A wet clean process treatment, as described in conjunction with FIGS. 13 and 14, may be performed on the surface of a substrate to remove the native oxide layer, particles and other contaminants. FIG. 14 illustrates an exemplary process sequence 301B that may performed in the cluster tool 101, that is illustrated in FIG. 15. FIG. 14 is similar to the process sequence 301A shown in FIG. 13 except that a preparation/analysis step 302C is performed before the performing the preparation/analysis step 302A. In one embodiment, the preparation/analysis step 302A includes a substrate preparation/analysis step (e.g., preparation/analysis step 302 in FIG. 5) or particle removal step as discussed above. In one embodiment, the preparation/analysis step 302C is a wet clean type substrate preparation step that is discussed below. In one embodiment, of the process sequence 301B, after performing the preparation/analysis step 302C the substrates proceeds to the substrate process step 304 and the substrate process step 306, which may be selected from one of the following group of semiconductor device forming processes that may include oxide etch, metal etch, EPI, RTP, DPN, PVD, CVD (e.g., BLOk, CVD polysilicon, TEOS etc.), or other suitable semiconductor substrate processing step.

FIG. 15 is a plan view of one embodiment of a cluster tool 101 that contains a processing region 120, a linking module 350 and a front-end environment 104. The processing region 120 generally contains the components discussed above in conjunction with FIG. 2, which generally includes one or more processing chambers 201-204, one ore more support chambers 211 (two are shown), a transfer chamber 110, and load lock chambers 106A-B. The load lock chambers 106A-B are in communication with the transfer chamber 110 and a linking module 350. It should be noted that the support chamber 211 may be positioned in other areas of the cluster tool, such as positions 114A-F, positions 214A-D and positions 354A-B in the linking module 350.

The linking module 350 generally has a transfer region 351 that connects the front-end environment 104 to the processing region 120. The linking module 350 generally contains a link robot 330 and one or more wet clean chambers 360. In one embodiment, the link robot 330 has a slide assembly 331 that is adapted to enable the link robot 330 to transfer substrates between the load lock chambers 106A-106B, the wet clean chambers 360 and support stage 104A within the front-end environment 104. The link robot 330 disposed in the transfer region 351 of the linking module 350 is generally capable of linear, rotational, and vertical movement to shuttle substrates between the load lock chambers 106 and the support stage 104A positioned which are mounted on the front-end environment 104. The front-end environment 104 is generally used to transfer substrates from a cassette (not shown) seated in the plurality of pods 105 through an atmospheric pressure clean environment/enclosure to some desired location, such as a the support stage 104A.

The wet clean chamber 360 is generally a chamber that is adapted to remove the native oxide layer and other contaminants found on an exposed substrate surface using one or more wet chemical processing steps. The wet clean chamber 360 may be an Emersion™ chamber or TEMPEST™ wet-clean chamber, available from Applied Materials, Inc. An example of an exemplary wet clean chamber 360 is further described in the commonly assigned U.S. patent application Ser. No. 09/891,849, filed Jun. 25, 2001, and the commonly assigned U.S. patent application Ser. No. 10/121,635, filed Apr. 11, 2002, which are both incorporated by reference herein in their entirety.

During processing the wet clean chamber 360 is generally configured to clean a surface of the substrate. In one aspect, the wet clean chamber is adapted to perform one or more process steps that cause compounds exposed on the surface of the substrate to terminate in a functional group. Functional groups attached and/or formed on the surface of the substrate include hydroxyls (OH), alkoxy (OR, where R=Me, Et, Pr or Bu), haloxyls (OX, where X=F, Cl, Br or I), halides (F, Cl, Br or I), oxygen radicals and aminos (NR or NR₂, where R=H, Me, Et, Pr or Bu). The wet cleaning process may expose the surface of the substrate to a reagent, such as NH₃, B₂H₆, SiH₄, SiH₆, H₂O, HF, HCl, O₂, O₃, H₂O, H₂O₂, H₂, atomic-H, atomic-N, atomic-O, alcohols, amines, plasmas thereof, derivatives thereof or combination thereof. The functional groups may provide a base for an incoming chemical precursor used in the subsequent CVD or atomic layer deposition (ALD) steps to attach on the surface of the substrate. In one embodiment, the wet clean process may expose the surface of the substrate to a reagent for a period from about 1 second to about 2 minutes. Wet clean process may also include exposing the surface of the substrate to an RCA solution (SC1/SC2), an HF-last solution, water vapor from WVG or ISSG systems, peroxide solutions, acidic solutions, basic solutions, plasmas thereof, derivatives thereof or combinations thereof. Useful wet clean processes are described in commonly assigned U.S. Pat. No. 6,858,547 and co-pending U.S. patent application Ser. No. 10/302,752, filed Nov. 21, 2002, entitled, “Surface Pre-Treatment for Enhancement of Nucleation of High Dielectric Constant Materials,” and published as U.S. 20030232501, which are both incorporated herein by reference in their entirety.

In one example of a wet clean process, a native oxide layer is removed prior to exposing substrate to a second process step that forms a chemical oxide layer having a thickness of about 10 Å or less, such as from about 5 Å to about 7 Å. Native oxides may be removed by a HF-last solution. The wet-clean process may be performed in a TEMPEST™ wet-clean system, available from Applied Materials, Inc. In another example, substrate is exposed to water vapor derived from a WVG system for about 15 seconds. A conventional HF-last processing step uses aqueous solutions that contain typically less than about 1% HF as the last step in the processing sequence to form a passivation layer on an exposed silicon surface. The HF-last process may be useful to reliably form a high quality gate oxide layer.

As noted in FIG. 14, after performing the preparation/analysis step 302A the substrate can then be processed using one or more substrate processing steps selected from one of the following group of processes that may include oxide etch, metal etch, EPI, RTP, DPN, PVD, CVD (e.g., CVD polysilicon, TEOS etc.), or other suitable semiconductor substrate processing step.

Process Enhancement Using A UV Clean Process

As semiconductor device sizes shrink, such as the 45 nm node or smaller, the queue time effects caused by native oxide growth, and/or exposure to organic contamination, become much more of an issue. To reduce the detrimental effect of native oxide growth, or contamination, on a formed semiconductor device one or more clean processes may be performed prior to performing a deposition step to assure that the surface of the substrate is at a desired cleanliness level. In one embodiment of the cluster tool, one or more of the processing chambers 201-204, or support chambers 211, contain a radiation source that is adapted to deliver one or more wavelengths of UV light to clean a surface of the substrate to reduce the queue time effect and thus prepare substrates for subsequent deposition processes, such as CVD, PVD, or ALD type processes. In this configuration the sequence of processing steps performed on a substrate in the cluster tool will include the step of cleaning the substrate surface using a source of UV energy (hereafter UV clean process). The addition of the UV clean process prior to the deposition step can be especially useful when it is performed just prior to performing an epitaxial (EPI) layer deposition step, since the nucleation of the deposited EPI layer and the stress in the formed EPI layer are very sensitive to the state of the surface at the beginning of the process. In one embodiment, a substrate processing sequence includes a preparation step, such as a wet clean type substrate preparation step (preparation/analysis step 302C in FIG. 14) or preclean processing step (preparation/analysis step 302B in FIG. 13), and a UV clean process step to enhance the cleanliness of the surface of the substrate and more repeatably control the state of the substrate surface just prior to performing a substrate fabrication step, such as a EPI, CVD, PVD, or ALD deposition process. The preparation steps, such as a wet clean type substrate preparation step or preclean processing step can thus be used to remove the bulk of the contamination or native oxide layer on the substrate surface, while the UV clean process is used to finally prepare and/or passivate the substrate surface just prior to the completion of a subsequent substrate processing step.

In one embodiment, the UV clean process is used to reduce the temperature at which a cleaning and/or passivation process is carried out versus other conventional cleaning techniques to reduce thermal budget concerns. For example, the substrate temperature during processing when using a desirable amount of UV radiation may be less than 750° C., and typically less than 700° C. In one aspect, the UV enhanced process is performed at a temperature ranging between about 500° C. and about 700° C. Conventional silicon-containing substrate cleaning and passivation steps, which are commonly used just prior to an EPI deposition step, are typically performed at a temperature ranging from about 750° C. and about 1,000° C. In one aspect, by treating a substrate in an ambient environment comprising hydrogen in the presence of UV radiation, it is possible to reduce either the temperature at which the cleaning and passivating process is carried out or the time required to clean the surface, or a combination of both. In one embodiment, the UV clean process is performed to prepare a clean and passivated silicon-containing substrate surface for the deposition of epitaxially-grown, silicon-containing films.

Referring to FIG. 6, in one embodiment, the particle reduction chamber 700 is further adapted to perform the cleaning process on the surface of the substrate. In one aspect, the particle reduction chamber 700 contains an enclosure 701, a radiation source 711, a substrate support 704, a heating element 722, a vacuum pump 736 and a gas delivery source 735 that is adapted to deliver a cleaning gas that contains a reducing gas, such as hydrogen to the processing region 710. In operation, the vacuum pump 736 is used to control the pressure in the processing region 710 between about 0.1 and about 80 Torr during the substrate surface cleaning and passivation process. The heating elements 722 and system controller 102 are used to control the substrate temperature during processing to ranges between about 550° C. and about 750° C., and typically ranges between about 550° C. and about 700° C. The system controller 102 and radiation source 711 are used to control the power density of the UV radiation to a range from about 1 mW/cm² to about 25 mW/cm² at one or more wavelengths between about 120 nm and about 430 nm.

In one example, the UV clean process is completed by exposing the substrate to clean gas containing hydrogen with simultaneous exposure to radiation at a wavelength of about 180 nm or lower. During the UV clean process the hydrogen flow rate is maintained in a range between about 25 slm and about 50 slm, while the temperature at the substrate surface was in the range of 500° C. to 650° C. for a time period ranging from about 1 minute to about 5 minutes. The pressure in the processing region may range from about 0.1 Torr to about 100 Torr, typically the pressure is in the range of about 5 Torr to about 30 Torr. The power density of the UV radiation delivered to the surface of the substrate may range from about 2 mW/cm² to about 25 mW/cm².

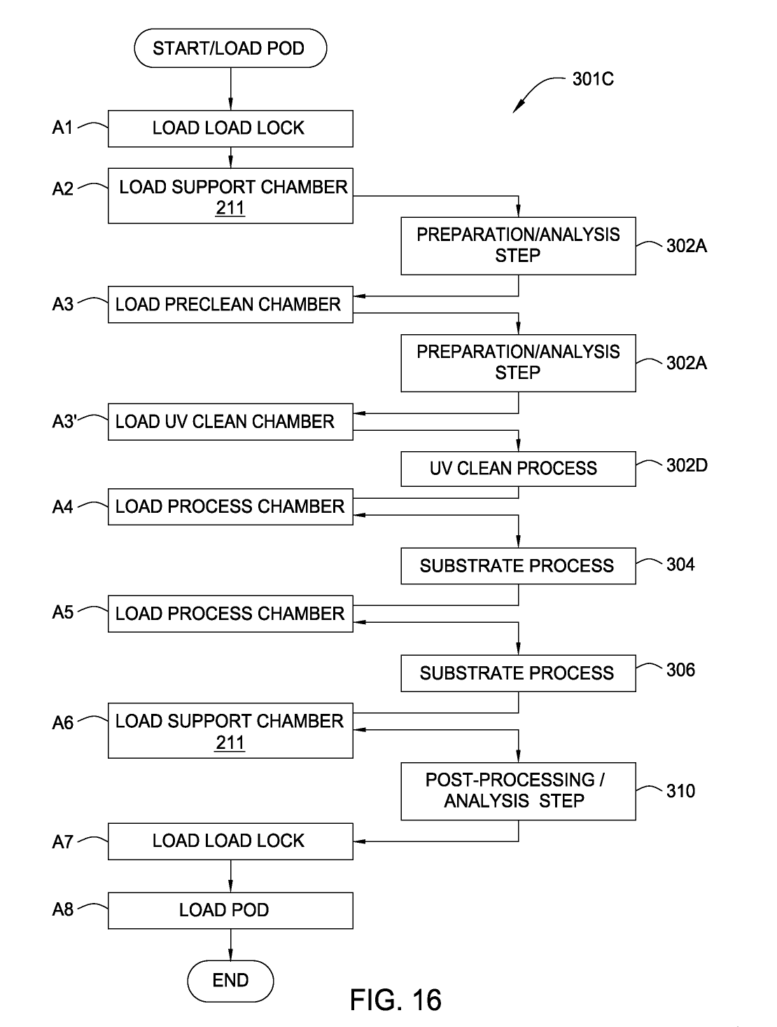

In one embodiment, as shown in FIG. 16, a UV clean process 302D is performed after performing the preclean process step 302B and prior to performing the process step 304. The process sequence 301C, illustrated in FIG. 16, is similar to the process sequence shown in FIG. 13 except that a transfer step A3′ and a UV clean process 302D have been added to perform the UV clean process 302D. It should be noted that FIG. 16 is not intended to limit the order in which the UV clean process may be performed within a processing sequence, since the cleaning process can be performed before or after anyone of the processing steps without varying from the basic scope the invention. In general, it is desirable to transfer or retain the substrate in a vacuum or inert environment after performing the UV clean process 302D to prevent or minimize the interaction of the substrate surface with oxygen or other contaminants to prevent native oxide growth or damage to the cleaned surface prior to performing the next substrate processing step. Therefore, it is generally desirable to perform the UV clean process within a cluster tool that has a low partial pressure of oxygen or other contaminants.

In another embodiment, a source of UV radiation, a substrate heater and a clean gas source are attached or contained within one or more of the processing chambers (e.g., processing chambers 201-204) mounted within the cluster tool so that the UV clean process can be performed therein. In this configuration the UV clean process may be performed in a process chamber prior to performing a deposition process and thus a separate transfer step A3′ (FIG. 16) is not needed. In one embodiment, a UV radiation source (not shown) is added to the preclean chamber 1100 illustrated in FIG. 12 to improve the process results of the preclean process preformed on the substrate surface.

In one embodiment, one or more metrology steps (e.g., preparation/analysis step 302A in FIGS. 13-14) are performed on the substrate after performing the UV cleaning process to analyze the state of various regions of the substrate so that corrective actions can be made by the system controller to improve the effectiveness of the UV clean process on subsequent substrates and/or improve the process results achieved in one or more of the subsequent processes. In general, the UV clean process variables may include the UV clean process time, the intensity of the UV power delivered to the substrate surface, and/or the substrate temperature.

In another embodiment, one or more metrology steps (e.g., preparation/analysis step 302A in FIGS. 13-14) are performed after the UV clean process has been performed and one or more subsequent substrate processing steps (e.g., PVD, CVD or ALD deposition steps) are performed on the substrate surface. In this case the metrology steps can be used to rapidly analyze the state of a region on the substrate surface to allow the system controller to make adjustments to one or more of the process variables within one or more of the process steps within the processing sequence to improve the achieved process results. In general, the process variables may include any of the UV clean process variables (e.g., UV clean process time, UV source power) or substrate processing process variables (e.g., RF power, process pressure, gas flow rate, film thickness, deposition rate, substrate temperature). In one example, an XRD device is used to measure and feedback the stress in a film deposited on the surface of a first substrate. Therefore, if the measured stress is out of a desired range the system controller can, for example, adjust the length of the UV clean process to improve the substrate surface cleanliness and reduce the stress in a deposited layer formed on a second substrate. This process can be important when used in cases where the deposited film properties (e.g., stress/strain) are very sensitive to the state of substrate surface prior to deposition, such as epixially deposited silicon layers.

The integration of the metrology step in the cluster tool allows the rapid feedback of desirable or undesirable process results after one or more processing steps in a process sequence to help reduce substrate scrap and device variability. The integrated metrology step within a cluster tool also improves the productivity of the cluster tool by possibly removing the need to waste time running test wafers or dummy wafers through the cluster tool to pre-qualify one or more of the process steps. Also, the use of one or more metrology chambers that are within, or in communication with, the controlled vacuum or inert environment regions of the cluster tool (e.g., transfer region 110) prevents and/or minimizes the interaction of the substrate surface with oxygen or other contaminants to provide more rapid and realistic metrology results versus process sequences that require the metrology steps to be performed outside of the controlled vacuum or inert environment. It is thus generally desirable to configure the cluster tool so that the metrology chamber(s) are attached to the cluster tool so that the transferring processes to and from the metrology chambers are performed within an environment that has a low partial pressure of oxygen or other contaminants.

UV Enhanced Deposition Processes

In one embodiment, a substrate processing chamber contains a UV radiation source that is adapted to reduce the substrate processing temperature during a substrate processing step (e.g., substrate process steps 304-306 in FIGS. 13, 14 and 16). The need to reduce the substrate processing temperatures is becoming increasingly important as the feature sizes are decreased to 45 nm , and below. The need to reduce the processing temperature is created by the need to minimize or avoid the device yield issues caused by the interdiffusion of materials between the layers of a formed device. Lower process temperatures are required for both substrate preparation steps and substrate fabrication steps. Reducing the substrate processing temperature improves the thermal budget of the formed device, which thus improves device yield and the useable lifetime of the formed device. It is thus desirable to use one or more process steps that contain a reduced processing temperature within a device fabrication processing sequence.

To accomplish this task, a substrate processing chamber, hereafter processing chamber, exposes one or more surfaces of a substrate to UV radiation during the step of performing the device fabrication process. When in use, the source of UV radiation is adapted to deliver enough energy to the surface of the substrate to reduce the need for thermal energy to cause the deposition or etching process to occur on the surface of the substrate. In general, it is believed that a radiation source that is adapted to deliver the UV radiation at wavelengths between about 120 and about 430 nanometers (nm) at a power density between about 5 and about 25 mWatts/cm² to a surface of the substrate is useful to assist most conventional CVD or ALD processes. It should be noted that the UV radiation wavelength and delivered power may need to be adjusted for a given temperature, precursor and substrate combinations. The radiation from the radiation source may be supplied by a lamp containing elements, such as xenon, argon, krypton, nitrogen, xenon chloride, krypton fluoride, argon fluoride. A typical radiation source may be a conventional UV lamp (e.g., mercury vapor lamp) or other similar device. Combinations of UV radiation sources having different emitted wavelengths may also be used. In one embodiment, the pressure during the processing chamber ranges between about 0.1 and about 80 Torr.

FIG. 16 illustrates a schematic side cross-sectional view of an exemplary process chamber 1600 which may be employed as one or more of the processing chambers 201-204 in the cluster tool 100 illustrated in FIGS. 2-3. In one embodiment, as shown in FIG. 16, the deposition process chamber includes stainless steel housing structure 1601 which encloses various functioning elements of the process chamber 1600. A quartz chamber 1630 includes an upper quartz chamber 1605 in which the UV radiation source 1608 is contained, and a lower quartz chamber 1624, in which a processing volume 1618 is contained. Reactive species are provided to processing volume 1618 and processing byproducts are removed from processing volume 1618. A substrate 1614 rests on a pedestal 1617, and the reactive species are applied to surface 1616 of the substrate 1614, with byproducts subsequently removed from surface 1616. Heating of the substrate 1614 and the processing volume 1618 is provided for using the infrared lamps 1610. Radiation from infrared lamps 1610 travels through upper quartz window 1604 of upper quartz chamber 1605 and through the lower quartz portion 1603 of lower quartz chamber 1624. One or more cooling gases for upper quartz chamber 1605 enter through inlet 1611 and exit 1613 through an outlet 1628. In one embodiment, where the process chamber is a CVD or ALD type process chamber a precursor, as well as diluent, purge and vent gases for lower quartz chamber 1624 enter through inlet 1620 and exit 1622 through outlet 1638. The outlets 1628 and 1638 are in communication with the same vacuum pump or are controlled to be at the same pressure using separate pumps, so that the pressure in upper quartz chamber 1605 and lower quartz chamber 1624 will be equalized. The UV radiation is thus used to energize reactive species and assist in adsorption of reactants and desorption of process byproducts from the surface 1616 of substrate 1614. An exemplary deposition chamber, UV clean process and process for depositing an EPI film using a UV assisted deposition process is further described in the commonly assigned U.S. patent application Ser. No. 10/866,471, filed Jun. 10, 2004, which is herein incorporated by reference in its entirety.

In one example, the deposition of a silicon nitride (SiN) film is carried out in the process chamber 1600 using a mixture of disilane (Si₂H₆) plus ammonia (NH₃) at a temperature preferably about 400° C. while UV radiation is delivered at a wavelength within the range of about 172 nm at a power density between about 5 and about 10 mWatts/cm². Typically, conventional SiN deposition processes require temperatures of about 650° C. or higher.

In one embodiment of the cluster tool, one or more metrology steps (e.g., preparation/analysis step 302A in FIGS. 13-14) are performed after performing one or more UV assisted substrate processing steps (e.g., a deposition step). In this case the metrology steps can be used to rapidly analyze the state of one or more layers deposited on the substrate surface to allow the system controller to make adjustments to the process variables in the substrate processing step to improve the process of forming the layer on the substrate surface. In general, the process variables may include, for example, UV radiation intensity (e.g., power), deposition time, process pressure, flow rate of process gases, RF power, film thickness, or substrate temperature. In one example, an XRD device is used to measure and feedback the stress in a film deposited on the surface of a first substrate so that the system controller can, for example, adjust the UV power during subsequent deposition processes to improve the film properties, such as stress, in layers formed using the UV assisted deposition process. This process can be important when used in cases where the deposited film properties (e.g., stress/strain) are very sensitive to the thermal environment during the deposition process. The integration of the metrology process step in the cluster tool allows the rapid feedback of desirable or undesirable process results achieved after one or more of the substrate fabrication process steps, which thus helps to improve device yield by reducing the number of misprocessed substrates and improve the productivity of the cluster tool by removing the need to waste time running test wafers through one or more of the process steps contained within a process sequence performed in the cluster tool to pre-qualify one or more of the processes performed within the process sequence.

While the foregoing is directed to embodiments of the present invention, other and further embodiments of the invention may be devised without departing from the basic scope thereof, and the scope thereof is determined by the claims that follow.

1. A substrate processing apparatus comprising:
one or more walls that form a transfer region that has a robot disposed therein;
a first support chamber disposed within the transfer region and adapted to measure a property of a surface of the substrate;
a substrate processing chamber in communication with the transfer region; and
a preclean chamber that is adapted to prepare a surface of a substrate before performing a processing step in the substrate processing chamber.

2. The apparatus of claim 1, wherein the transfer region is maintained at a pressure between about 10⁻⁶ Torr and about 700 Torr.

3. The apparatus of claim 1, wherein the first support chamber is adapted to measure a property of a surface of a substrate using a XRD, XPS, reflectometer, or ellipsometer techniques.

4. The apparatus of claim 1, wherein the substrate processing chamber is a decoupled plasma nitride (DPN) chamber, an rapid thermal processing (RTP) chamber, a chemical vapor deposition (CVD) chamber, an atomic layer deposition (ALD) chamber, or a physical vapor deposition (PVD) chamber.

5. The apparatus of claim 1, further comprising a second support chamber that is adapted to remove contamination from a surface of a substrate, wherein the contamination is removed by delivering ultraviolet (UV) radiation to a surface of the substrate from a source disposed on the one or more walls.

6. The apparatus of claim 1, wherein the property of the surface of the substrate measured in the first support chamber is a property selected from a group consisting of stress, strain, thickness and composition of material contained within the region.

7. A substrate processing apparatus comprising:
one or more walls that form a transfer region that has a robot disposed therein;
one or more substrate processing chambers that are in communication with the transfer region;
a support chamber that is in transferable communication with the robot, wherein the support chamber is adapted to measure a property of a surface of the substrate; and
a processing chamber that is in communication with the transfer region, wherein the processing chamber comprises:
a substrate support positioned within a processing region of the processing chamber; and
a first radiation source that is adapted to deliver one or more UV wavelengths of light to a surface of a substrate that is positioned on the substrate support.

8. The apparatus of claim 7, wherein the transfer region is maintained at a pressure between about 10⁻⁶ Torr and about 700 Torr.

9. The apparatus of claim 7, wherein the one or more substrate processing chambers is a decoupled plasma nitride (DPN) chamber, an rapid thermal processing (RTP) chamber, a chemical vapor deposition (CVD) chamber, or an atomic layer deposition (ALD) chamber.

10. The apparatus of claim 7, wherein the support chamber is adapted to measure a property of a surface of a substrate using a XRD, XPS, reflectometer, or ellipsometer techniques.

11. The apparatus of claim 7, further comprising a second support chamber that is adapted to remove contamination from a surface of a substrate, wherein the contamination is removed by delivering ultraviolet (UV) radiation to a surface of the substrate from a second radiation source connected to at least one of the one or more walls.

12. The apparatus of claim 7, wherein the first radiation source that is adapted to deliver one or more wavelengths of light in a range between about 120 nm and about 430 nm at a power density between about 1 and about 25 mWatts/cm².

13. The apparatus of claim 7, wherein the process chamber further comprises a gas source that is adapted to deliver a cleaning gas to the processing region, wherein the cleaning gas contains hydrogen.

14. The apparatus of claim 7, further comprising:
a pod that is adapted to contain two or more substrates;
a load lock in communication with the robot, wherein the load lock is adapted to be evacuated to a pressure below atmospheric pressure; and
a second robot that is adapted to transfer one of the two or more substrates positioned in the pod between the pod and the load lock.

15. The apparatus of claim 7, wherein the property of the surface of the substrate measured in the support chamber is a property selected from a group consisting of stress, strain, thickness and composition of material contained within the region.

16. A substrate processing apparatus comprising:
one or more walls that form a transfer region that has a robot disposed therein;
a support chamber that is in transferable communication with the robot, wherein the support chamber is adapted to measure a property of a surface of the substrate;
a first processing chamber that is in communication with the transfer region, wherein the first processing chamber comprises:
a substrate support positioned within a processing region of the processing chamber; and
a first radiation source that is adapted to deliver one or more UV wavelengths of light to a surface of a substrate that is positioned on the substrate support; and
a second processing chamber that is in communication with the transfer region, wherein the second processing chamber comprises:
a substrate support positioned within a processing region of the processing chamber;
a second radiation source that is adapted to deliver one or more UV wavelengths of light to a surface of a substrate that is positioned on the substrate support; and
a gas source that is adapted to deliver a cleaning gas to the processing region, wherein the cleaning gas contains hydrogen.

17. The apparatus of claim 16, wherein the transfer region is maintained at a pressure between about 10⁻⁶ Torr and about 700 Torr.

18. The apparatus of claim 16, wherein the first processing chamber is a decoupled plasma nitride (DPN) chamber, an rapid thermal processing (RTP) chamber, a chemical vapor deposition (CVD) chamber, or an atomic layer deposition (ALD) chamber.

19. The apparatus of claim 16, wherein the support chamber is adapted to measure a property of a surface of a substrate using a XRD, XPS, reflectometer, or ellipsometer techniques.

20. The apparatus of claim 16, further comprising a second support chamber that is adapted to remove contamination from a surface of a substrate, wherein the contamination is removed by delivering ultraviolet (UV) radiation to a surface of the substrate from a second radiation source connected to at least one of the one or more walls.

21. The apparatus of claim 16, wherein the first and second radiation sources are adapted to deliver one or more wavelengths of light in a range between about 120 nm and about 430 nm at a power density between about 1 and about 25 mWatts/cm².

22. The apparatus of claim 16, wherein the property of the surface of the substrate measured in the support chamber is a property selected from a group consisting of stress, strain, thickness and composition of material contained within the region.

23. A method of forming a semiconductor device in a cluster tool, comprising:
modifying a surface of a substrate in a substrate processing chamber;
measuring a property of a region of the substrate after modifying the surface of the substrate;
comparing the measured property with values stored in a system controller; and
modifying a process variable during the modifying a surface of a substrate process based on the comparison of the measured property and the values stored in the system controller.

24. The method of claim 23, wherein measuring a property of a region includes measuring a property selected from a group consisting of stress, strain, thickness and composition of material contained within the region.

25. The method of claim 23, further comprising precleaning the surface of the substrate prior to modifying the surface of the substrate.

26. The method of claim 23, further comprising removing contamination from the surface of the substrate before forming the device feature, wherein removing contamination comprises:
exposing a surface of the substrate to radiation having at least one wavelength within a range between about 120 nm and about 430 nm ;
providing a cleaning gas to that contains hydrogen to the surface of the substrate; and
heating the substrate to a temperature below about 750° C.

27. The method of claim 23, wherein modifying a surface of a substrate comprises performing a process selected from a group consisting of a decoupled plasma nitride (DPN) process, an epitaxial-layer (EPI) deposition process, a rapid thermal processing (RTP) process, a chemical vapor deposition (CVD) process, an atomic layer deposition (ALD) process, and a physical vapor deposition (PVD) process.

28. The method of claim 27, wherein modifying a surface of a substrate further comprises exposing a surface of the substrate to radiation having at least one wavelength within a range between about 120 nm and about 430 nm during the modifying a surface processing step.

29. A method of forming a semiconductor device in a cluster tool, comprising:
modifying a surface of a substrate in a substrate processing chamber;
positioning a substrate in a transferring region of the cluster tool using a robot that is disposed within the transferring region;
measuring a property of the surface of the substrate that is positioned in the transferring region;
comparing the measured property with values stored in a system controller; and
adjusting a process variable in the modifying a surface of a substrate process based on the comparison of the measured property and the values stored in the system controller.

30. The method of claim 29, further comprising precleaning the surface of the substrate prior to forming a device feature.

31. The method of claim 29, wherein measuring a property of a region includes measuring a property selected from a group consisting of stress, strain, thickness and composition of material contained within the region.

32. The method of claim 29, further comprising removing contamination from the surface of the substrate before forming the device feature by exposing a surface of the substrate to ultraviolet (UV) radiation from a radiation source.

33. The method of claim 29, wherein modifying a surface of a substrate comprises performing a process selected from a group consisting of a decoupled plasma nitride (DPN) process, an epitaxial-layer (EPI) deposition process, a rapid thermal processing (RTP) process, a chemical vapor deposition (CVD) process, an atomic layer deposition (ALD) process, and a physical vapor deposition (PVD) process.

34. The method of claim 29, further comprising removing contamination from the surface of the substrate before forming the device feature, wherein removing contamination comprises:
exposing a surface of the substrate to radiation having at least one wavelength within a range between about 120 nm and about 430 nm ;
providing a cleaning gas to that contains hydrogen to the surface of the substrate; and
heating the substrate to a temperature below about 750° C.

35. The method of claim 29, wherein modifying a surface of a substrate further comprises exposing a surface of the substrate to radiation having at least one wavelength within a range between about 120 nm and about 430 nm during the modifying a surface processing step.
